(19) United States
(12) Patent Application Publication
(10) Pub. No.: US 2025/0239305 A1
(43) Pub. Date: Jul. 24, 2025

(54) THREE-DIMENSIONAL MEMORY DEVICE HAVING DIFFERENT SHAPE SUPPORT PILLAR STRUCTURES

(71) Applicant: SANDISK TECHNOLOGIES LLC, ADDISON, TX (US)

(72) Inventor: Akira TAKAHASHI, Yokkaichi (JP)

(21) Appl. No.: 18/417,130

(22) Filed: Jan. 19, 2024

(51) Int. Cl. G11C 16/04; G11C 5/06; H01L 23/522; H01L 23/528; H10B 41/10; H10B 41/27; H10B 41/35; H10B 43/10; H10B 43/27; H10B 43/35

(52) U.S. Cl. CPC G11C 16/0483; G11C 5/063; H01L 23/5226; H01L 23/5283; H10B 41/10; H10B 41/27; H10B 41/35; H10B 43/10; H10B 43/27; H10B 43/35

(57) ABSTRACT

A three-dimensional memory device includes an alternating stack of insulating layers and electrically conductive layers, memory stack structures vertically extending through the alternating stack, and each of the memory stack structures includes a respective vertical stack of memory elements and a vertical semiconductor channel, support pillar structures vertically extending through the alternating stack in a contact region, and word-line-contact via structures located within the contact region and electrically contacting a respective one of the electrically conductive layers. The support pillar structures include laterally-elongated support pillar structures having a respective laterally-elongated horizontal cross-sectional shape, and cylindrical support pillar structures having a respective circular cross-sectional shape. Each of the word-line-contact via structures is laterally surrounded by a respective set of at least three laterally-elongated support pillar structures.

### FIELD

The present disclosure relates generally to the field of semiconductor devices, and particularly to three-dimensional memory devices including different shape support pillar structures.

### BACKGROUND

A three-dimensional memory device including three-dimensional vertical NAND strings having one bit per cell are disclosed in an article by T. Endoh et al, titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a three-dimensional memory device includes an alternating stack of insulating layers and electrically conductive layers, memory stack structures vertically extending through the alternating stack, and each of the memory stack structures includes a respective vertical stack of memory elements and a vertical semiconductor channel, support pillar structures vertically extending through the alternating stack in a contact region, and word-line-contact via structures located within the contact region and electrically contacting a respective one of the electrically conductive layers. The support pillar structures include laterally-elongated support pillar structures having a respective laterally-elongated horizontal cross-sectional shape, and cylindrical support pillar structures having a respective circular cross-sectional shape. Each of the word-line-contact via structures is laterally surrounded by a respective set of at least three laterally-elongated support pillar structures.

### BRIEF DESCRIPTION OF THE DRAWINGS

FIG. 1 is a plan view of a semiconductor die according to an embodiment of the present disclosure.

FIG. 2 is a vertical cross-sectional view of an exemplary structure after formation of an alternating layer stack of insulating layers and sacrificial material layers according to an embodiment of the present disclosure. The view shown in FIG. 2 corresponds to a vertical cross-sectional view of region M1 in FIG. 1.

FIG. 3 is a vertical cross-sectional view of the exemplary structure after formation of stepped surfaces and a retro-stepped dielectric material portion according to an embodiment of the present disclosure.

FIG. 4A is a first additional vertical cross-sectional view of the exemplary structure after formation of a retro-stepped dielectric material portion according to an embodiment of the present disclosure. FIG. 4B is a second additional vertical cross-sectional view of the exemplary structure of FIG. 4A. FIG. 4C is a top-down view of the alternative configuration of the exemplary structure of FIGS. 4A and 4B. The vertical plane A-A′ is the cut plane of the vertical cross-sectional view of FIG. 4A. The vertical plane B-B′ is the cut plane of the vertical cross-sectional view of FIG. 4B.

FIG. 5A is a vertical cross-sectional view of the exemplary structure after formation of memory openings and support openings according to an embodiment of the present disclosure. FIGS. 5B-5H are top-down views of various configurations of the exemplary structure of FIG. 5A.

FIG. 6 is a vertical cross-sectional view of the exemplary structure after formation of sacrificial opening fill structures according to an embodiment of the present disclosure.

FIG. 7 is a vertical cross-sectional view of the exemplary structure after removal of sacrificial support opening fill structures according to an embodiment of the present disclosure.

FIG. 8A is a vertical cross-sectional view of the exemplary structure after formation of dielectric pillar structures according to an embodiment of the present disclosure.

FIGS. 8B-8H are top-down views of various configurations of the exemplary structure of FIG. 8A.

FIG. 9 is a vertical cross-sectional view of the exemplary structure after removal of the sacrificial memory opening fill structures from the memory openings according to an embodiment of the present disclosure.

FIGS. 10A-10F are sequential vertical cross-sectional views of a region around a memory opening during formation of a memory opening fill structure according to an embodiment of the present disclosure.

FIG. 11A is a vertical cross-sectional view of the exemplary structure after formation of memory opening fill structures according to an embodiment of the present disclosure. FIGS. 11B-11H are top-down views of various configurations of the exemplary structure of FIG. 11A.

FIG. 12A is a vertical cross-sectional view of the exemplary structure after formation of a contact-level dielectric layer and lateral isolation trenches according to an embodiment of the present disclosure. FIG. 12B is another vertical cross-sectional view of the exemplary structure of FIG. 12A. FIG. 12C is a top-down view of the exemplary structure of FIGS. 12A and 12B. The vertical plane A-A′ is the cut plane of the vertical cross-sectional view of FIG. 12A. The vertical plane B-B′ is the cut plane of the vertical cross-sectional view of FIG. 12B.

FIG. 13 is a vertical cross-sectional view of the exemplary structure after formation of laterally-extending cavities according to an embodiment of the present disclosure.

FIG. 14A is a vertical cross-sectional view of the exemplary structure after formation of electrically conductive layers according to an embodiment of the present disclosure. FIG. 14B is another vertical cross-sectional view of the exemplary structure of FIG. 14A. FIG. 14C is a top-down view of the exemplary structure of FIGS. 14A and 14B. The vertical plane A-A′ is the cut plane of the vertical cross-sectional view of FIG. 14A. The vertical plane B-B′ is the cut plane of the vertical cross-sectional view of FIG. 14B.

FIG. 15A is a vertical cross-sectional view of the exemplary structure after formation of lateral isolation trench fill structures according to an embodiment of the present disclosure. FIG. 15B is another vertical cross-sectional view of the exemplary structure of FIG. 15A. FIG. 15C is a top-down view of the exemplary structure of FIGS. 15A and 15B. The vertical plane A-A′ is the cut plane of the vertical cross-sectional view of FIG. 15A. The vertical plane B-B′ is the cut plane of the vertical cross-sectional view of FIG. 15B.

FIG. 16A is a vertical cross-sectional view of the exemplary structure after formation of layer contact via structures and drain contact via structures according to an embodiment of the present disclosure. FIG. 16B is a top-down view of the exemplary structure of FIG. 16A. FIGS. 16C-161 are top-down views of various configurations of the exemplary structure of FIGS. 16A and 16B.

### DETAILED DESCRIPTION

As discussed above, the embodiments of the present disclosure are directed to three-dimensional memory devices including different shape dielectric pillar structures which reduce buckling of the alternating stack during word line formation and methods of forming the same, the various aspects of which are now described in detail.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or to each other, the two elements are “disjoined from” each other or “disjoined among” one another. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a first element is “electrically connected to” a second element if there exists a conductive path consisting of at least one conductive material between the first element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the first continuous structure. For example, a layer may be located between any pair of horizontal planes between, or at, a top surface and a bottom surface of the first continuous structure. A layer may extend horizontally, vertically, and/or along a tapered surface. A substrate may be a layer, may include one or more layers therein, or may have one or more layer thereupon, thereabove, and/or therebelow.

As used herein, a first surface and a second surface are “vertically coincident” with each other if the second surface overlies or underlies the first surface and there exists a vertical plane or a substantially vertical plane that includes the first surface and the second surface. A substantially vertical plane is a plane that extends straight along a direction that deviates from a vertical direction by an angle less than 5 degrees. A vertical plane or a substantially vertical plane is straight along a vertical direction or a substantially vertical direction, and may, or may not, include a curvature along a direction that is perpendicular to the vertical direction or the substantially vertical direction.

As used herein, a “memory level” or a “memory array level” refers to the level corresponding to a general region between a first horizontal plane (i.e., a plane parallel to the top surface of the substrate) including topmost surfaces of an array of memory elements and a second horizontal plane including bottommost surfaces of the array of memory elements. As used herein, a “through-stack” element refers to an element that vertically extends through a memory level.

As used herein, a “semiconducting material” refers to a material having electrical conductivity in the range from 1.0×10⁻⁵ S/m to 1.0×10⁵ S/m. As used herein, a “semiconductor material” refers to a material having electrical conductivity in the range from 1.0×10⁻⁵ S/m to 1.0 S/m in the absence of electrical dopants therein, and is capable of producing a doped material having electrical conductivity in a range from 1.0 S/m to 1.0×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

The various three-dimensional memory devices of the present disclosure include a monolithic three-dimensional NAND string memory device, and may be fabricated using the various embodiments described herein. The monolithic three-dimensional NAND string is located in a monolithic, three-dimensional array of NAND strings located over the substrate. At least one memory cell in the first device level of the three-dimensional array of NAND strings is located over another memory cell in the second device level of the three-dimensional array of NAND strings.

Generally, a semiconductor package (or a “package”) refers to a unit semiconductor device that may be attached to a circuit board through a set of pins or solder balls. A semiconductor package may include a semiconductor chip (or a “chip”) or a plurality of semiconductor chips that are bonded throughout, for example, by flip-chip bonding or another chip-to-chip bonding. A package or a chip may include a single semiconductor die (or a “die”) or a plurality of semiconductor dies. A die is the smallest unit that may independently execute external commands or report status. Typically, a package or a chip with multiple dies is capable of simultaneously executing as many number of external commands as the total number of dies therein. Each die includes one or more planes. Identical concurrent operations may be executed in each plane within a same die, although there may be some restrictions. In case a die is a memory die, i.e., a die including memory elements, concurrent read operations, concurrent write operations, or concurrent erase operations may be performed in each plane within a same memory die. In a memory die, each plane contains a number of memory blocks (or “blocks”), which are the smallest unit that may be erased by in a single erase operation. Each memory block contains a number of pages, which are the smallest units that may be selected for programming. A page is also the smallest unit that may be selected to a read operation.

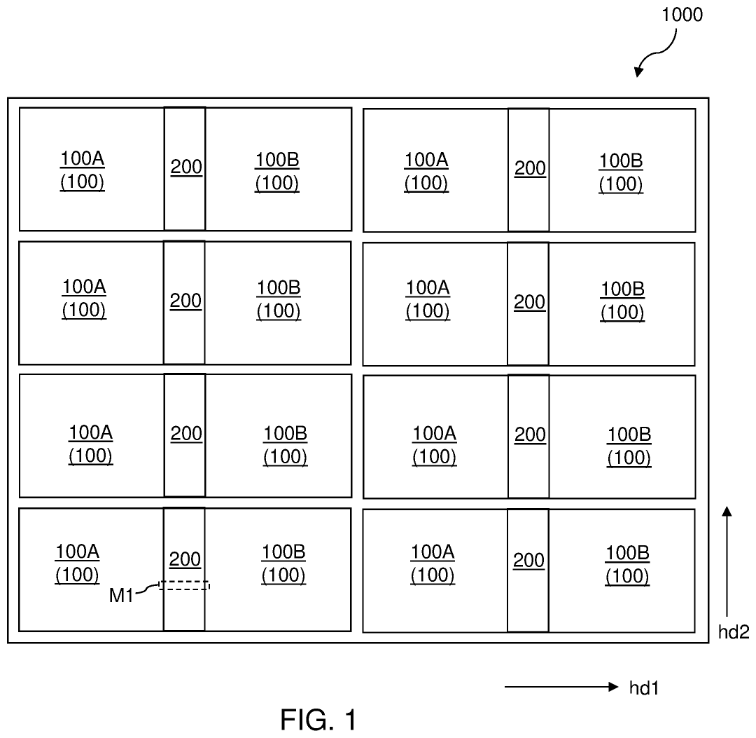

Referring to FIG. 1, a memory die 1000 is illustrated, which comprises multiple planes. Each plane may comprises at least one memory array region 100, such as a first memory array region 100A and a second memory array region 100B that are laterally spaced apart by a respective contact region 200. Generally, a memory die 1000 may include a single plane or multiple planes. The total number of planes in the memory die may be selected based on performance requirements on the memory die 1000. A pair of memory array regions 100 in a plane may be laterally spaced apart along a first horizontal direction hd1 (which may be the word line direction). For example, each pair of memory array regions 100 in a plane may include first memory array region 100A and a second memory array region 100B that are laterally spaced apart along the first horizontal direction hd1 by the contact region 200. A second horizontal direction hd2 (which may be the bit line direction) can be perpendicular to the first horizontal direction hd1. The memory die 1000 illustrated in FIG. 1 can be manufactured employing various embodiments of the present disclosure to be described below. Specifically, region M1 in FIG. 1 is illustrated in detail in subsequent figures.

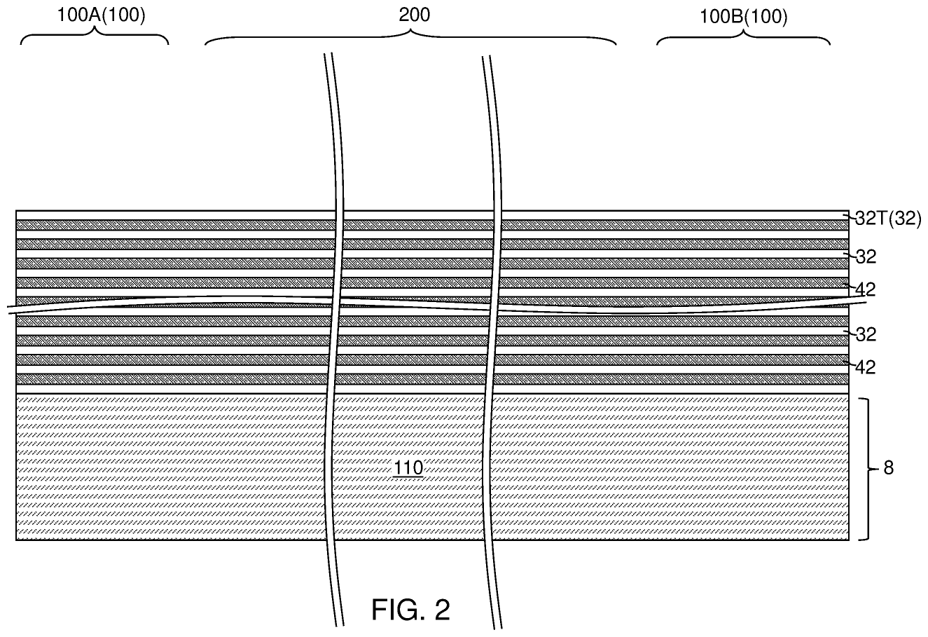

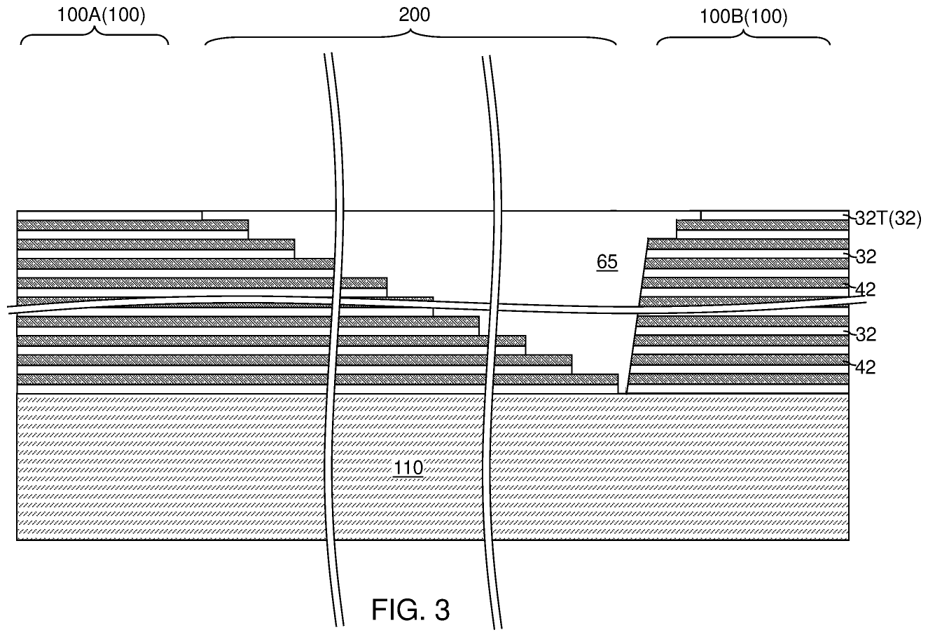

Referring to FIG. 2, a vertical cross-sectional view of a first exemplary structure for forming the memory die of FIG. 1 is illustrated. The first exemplary structure may comprise a substrate 8 containing a semiconductor material layer 110. The substrate may comprise a silicon wafer, a silicon on insulator substrate, or another substrate. The semiconductor material layer 110 may comprise a single crystalline or polycrystalline semiconductor layer, such as a single crystalline silicon layer or a polysilicon layer, and may comprise a doped well in a top portion of a silicon wafer substrate 8, a silicon layer deposited over the substrate 8, a silicon layer bonded to the substrate 8, etc.

An alternating stack (32, 42) of insulating layers 32 and spacer material layers can be formed over the semiconductor material layer 110. The spacer material layers are formed as, or are subsequently replaced with, electrically conductive layers. In case the spacer material layers are subsequently replaced with the electrically conductive layers, the spacer material layers may be formed as sacrificial material layers 42.

As used herein, an alternating stack refers to a sequence of multiple instances of a first element and multiple instances of a second element that is arranged such that an instance of a second element is located between each vertically neighboring pair of instances of the first element, and an instance of a first element is located between each vertically neighboring pair of instances of the second element. An alternating stack refers to a sequence of multiple instances of a first material layer and multiple instances of a second material layer such that the instances of the first material layer and the instances of the second material layer are interlaced.

The insulating layers 32 can be composed of the first material, and the sacrificial material layers 42 can be composed of the second material, which is different from the first material. Each of the insulating layers 32 continuously extends over the entire area of the substrate 8, and may have a uniform thickness throughout. Each of the sacrificial material layers 42 includes a sacrificial dielectric material and continuously extends over the entire area of the substrate 8, and may have a uniform thickness throughout. Insulating materials that may be used for the insulating layers 32 include, but are not limited to silicon oxide (including doped or undoped silicate glass), silicon nitride, silicon oxynitride, organosilicate glass (OSG), spin-on dielectric materials, dielectric metal oxides that are commonly known as high dielectric constant (high-k) dielectric oxides (e.g., aluminum oxide, hafnium oxide, etc.) and silicates thereof, dielectric metal oxynitrides and silicates thereof, and organic insulating materials. In one embodiment, the first material of the insulating layers 32 may be silicon oxide.

The second material of the sacrificial material layers 42 is a dielectric material, which is a sacrificial material that may be removed selective to the first material of the insulating layers 32. As used herein, a removal of a first material is “selective to” a second material if the removal process removes the first material at a rate that is at least twice the rate of removal of the second material. The ratio of the rate of removal of the first material to the rate of removal of the second material is herein referred to as a “selectivity” of the removal process for the first material with respect to the second material. The second material of the sacrificial material layers 42 may be subsequently replaced with electrically conductive electrodes which may function, for example, as control gate electrodes of a vertical NAND device. In one embodiment, the sacrificial material layers 42 may be material layers that comprise silicon nitride.

Each insulating layer 32 may have a first thickness, which may be in a range from 15 nm to 60 nm, although lesser and greater thicknesses may also be employed. Each sacrificial material layer 42 may have a second thickness, which may be in a range from 15 nm to 60 nm, although lesser and greater thicknesses may also be employed. The total number of repetitions of a pair of an insulating layer 32 and a sacrificial material layer 42 in the alternating stack (32, 42) may be in a range from 16 to 1,024, such as from 64 to 512, although lesser and greater numbers may also be employed. The topmost layer among the insulating layers 32 is herein referred to as a topmost insulating layer 32T.

Generally, an alternating stack (32, 42) of insulating layers 32 and sacrificial material layers 42 can be formed over the substrate 8. The alternating stack (32, 42) comprises a first memory array region 100A, a second memory array region 100B that is laterally spaced from the first memory array region 100A along a first horizontal direction hd1, and a contact region 200 that is located between the first memory array region 100A and the second memory array region 100B.

Referring to FIG. 3, stepped surfaces can be formed in the contact region 200 by patterning the alternating stack (32, 42). A retro-stepped dielectric material portion 65 can be formed over each set of stepped surfaces.

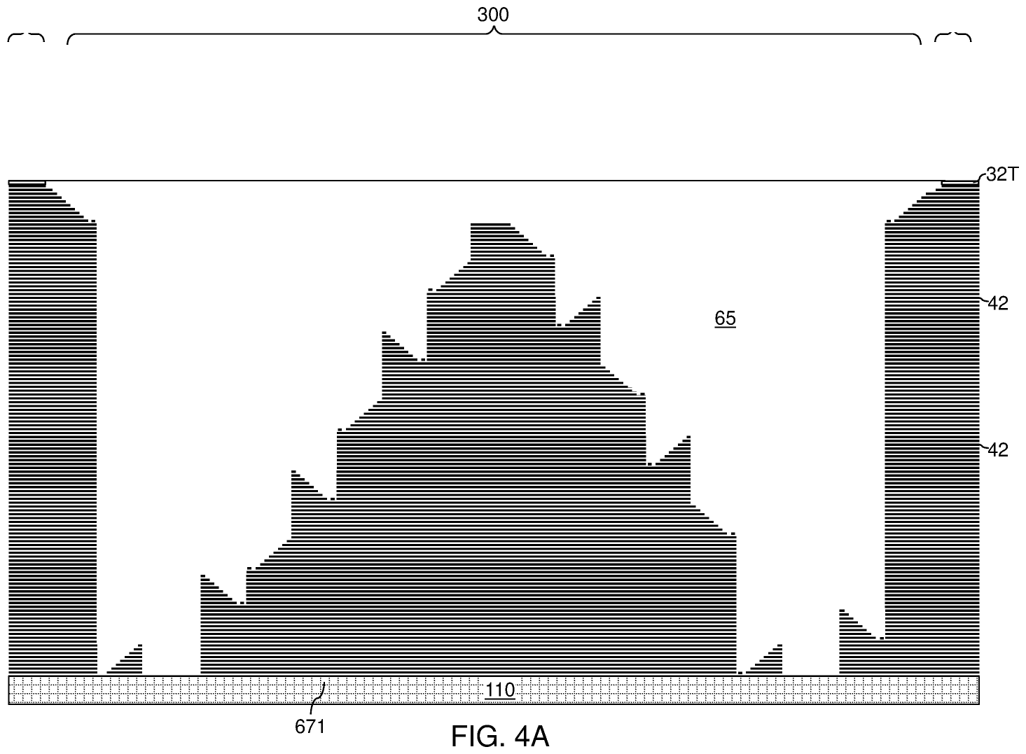

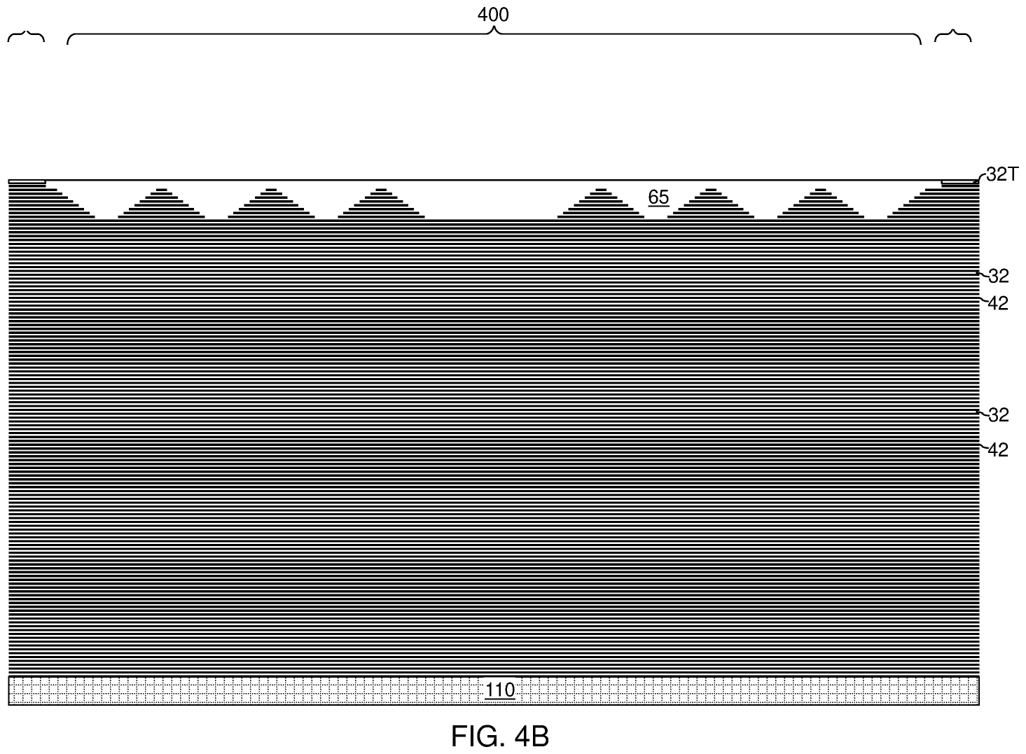

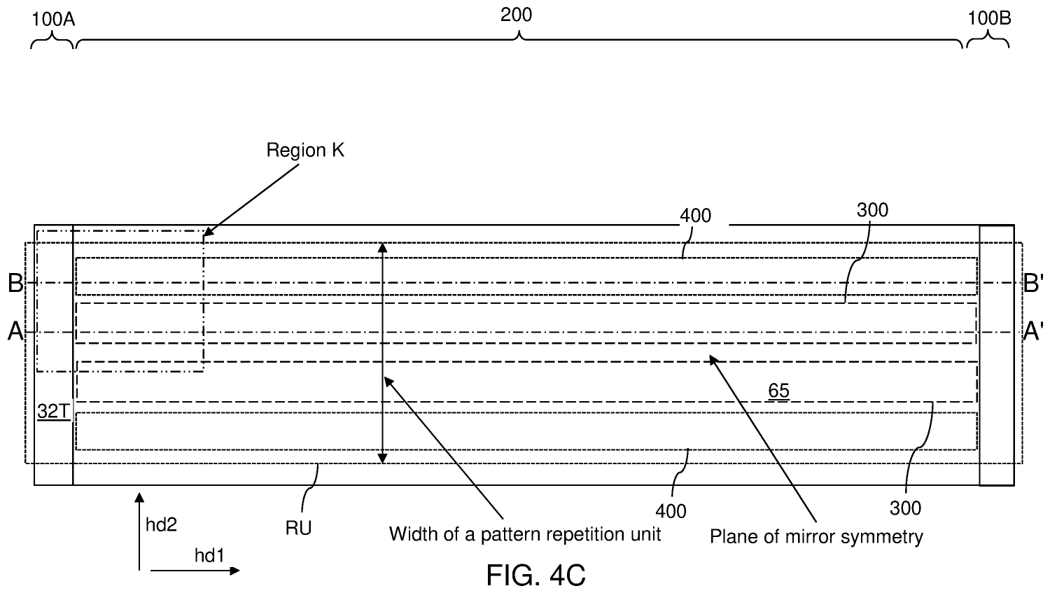

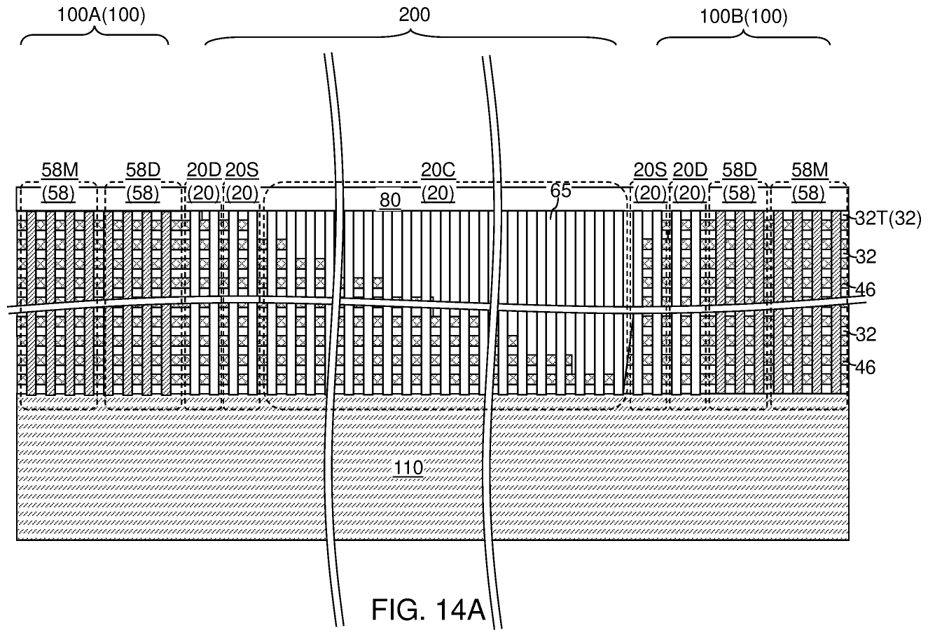

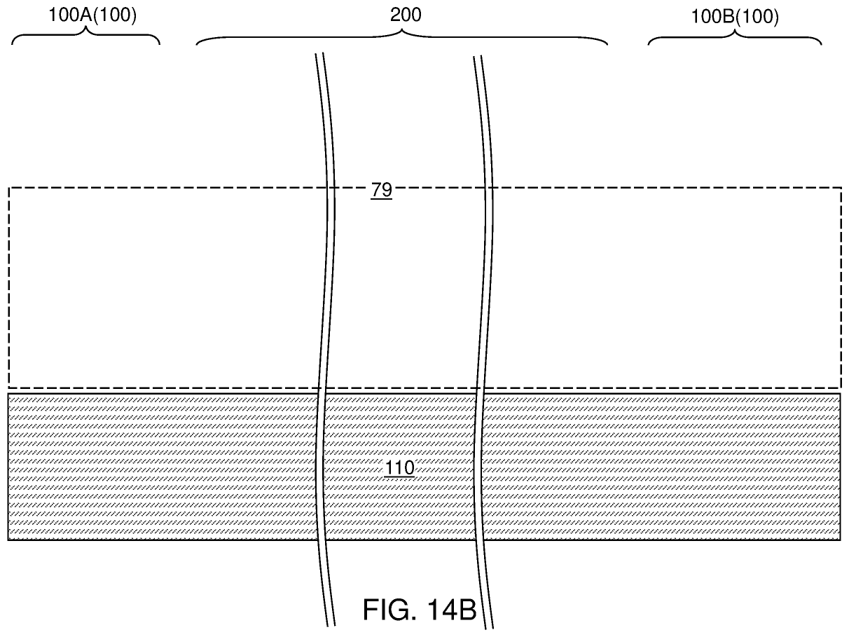

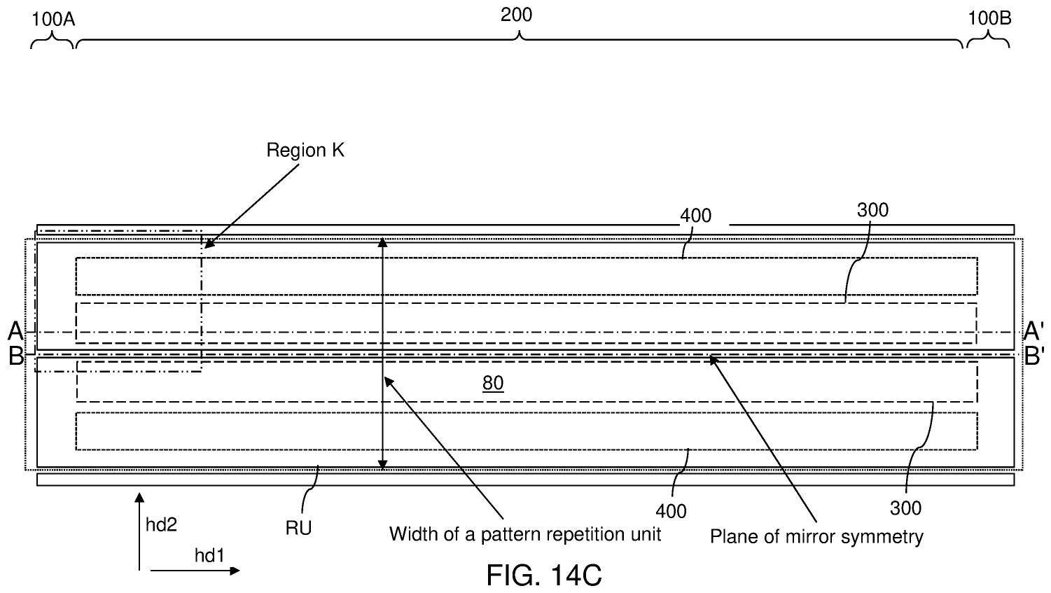

Referring to FIGS. 4A-4C, additional views of the exemplary structure is shown after the processing steps of FIG. 3. The exemplary structure may comprise multiple repetition units RU that are repeated along the second horizontal direction hd2. Each portion of a repetition unit RU that is located within a contact region 200 may comprise, from one side to another, a first connection (e.g., bridge) region 400, a first staircase region 300, a second staircase region 300, and a second connection region 400. Each combination of a first connection region 400, a first staircase region 300, a second staircase region 300, and a second connection region 400 may have a plane of mirror symmetry that is perpendicular to the second horizontal direction hd2. At least a majority of the sacrificial material layers 42 extend continuously from the first memory array region 100A to the second memory array region 100B through the contact region 200 in one or both of the first and second connection regions 400. For example, all sacrificial material layers 42, or at least 80 percent, such as at least 90 percent of the sacrificial material layers 42 counted from the bottom of the alternating stack (32, 42) extend continuously from the first memory array region 100A to the second memory array region 100B through the contact region 200 in one or both of the first and second connection regions 400. As shown in FIG. 4B, at least one topmost sacrificial material layer 42 does not extend continuously from the first memory array region 100A to the second memory array region 100B through the contact region 200 in one or both of the first and second connection regions 400. In this case, after the sacrificial material layers 42 are replaced with electrically conductive layers (as shown in FIGS. 14A-14C and described below), the portions of each of the topmost electrically conductive layers which do not extend continuously from the first memory array region 100A to the second memory array region 100B through the contact region 200 may be electrically connected to each other by overlying electrically conductive interconnects which are formed after the electrically conductive layers.

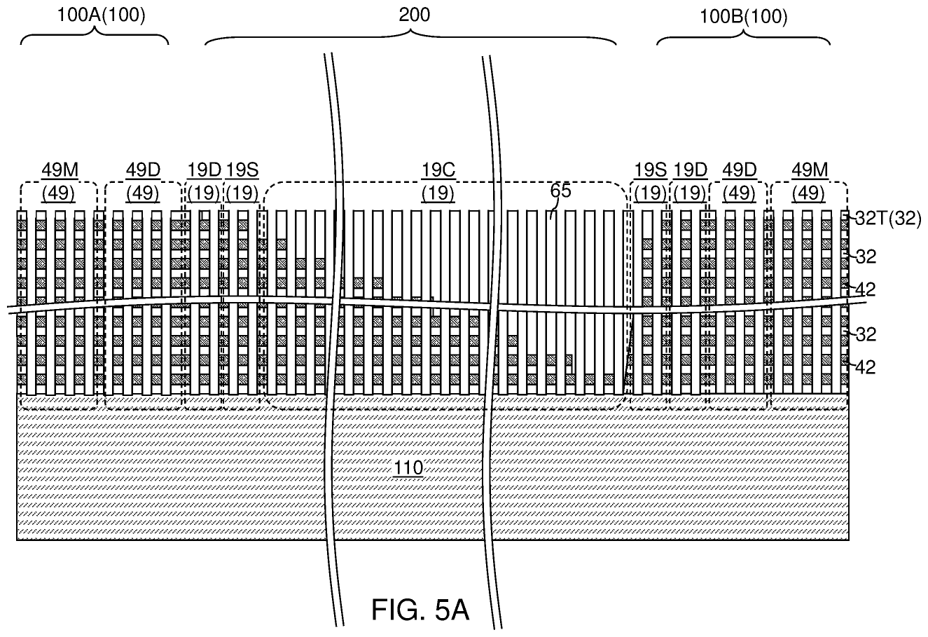

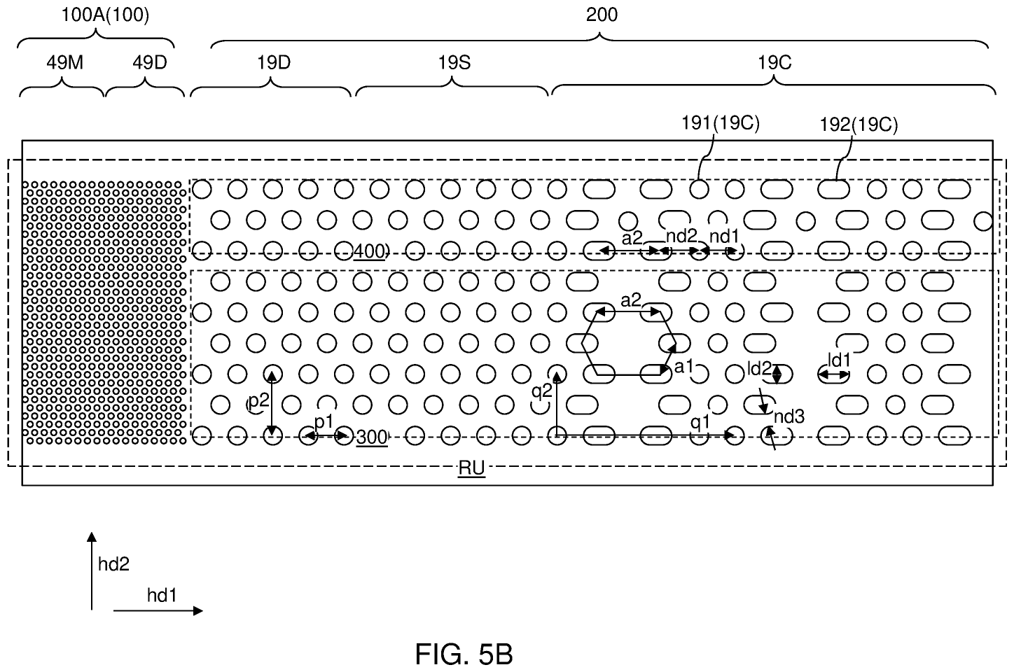

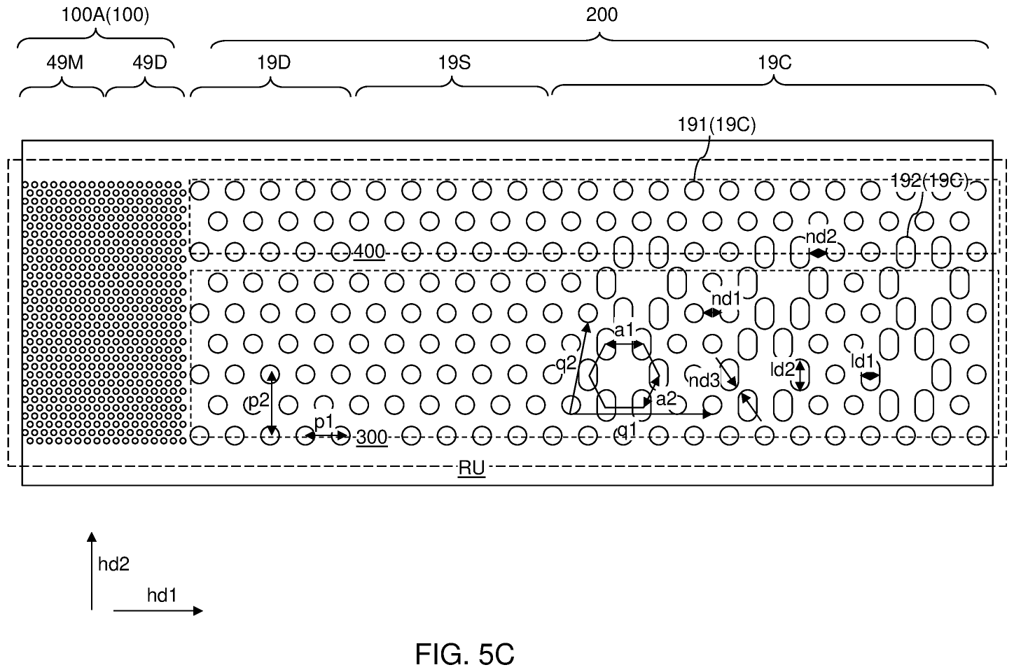

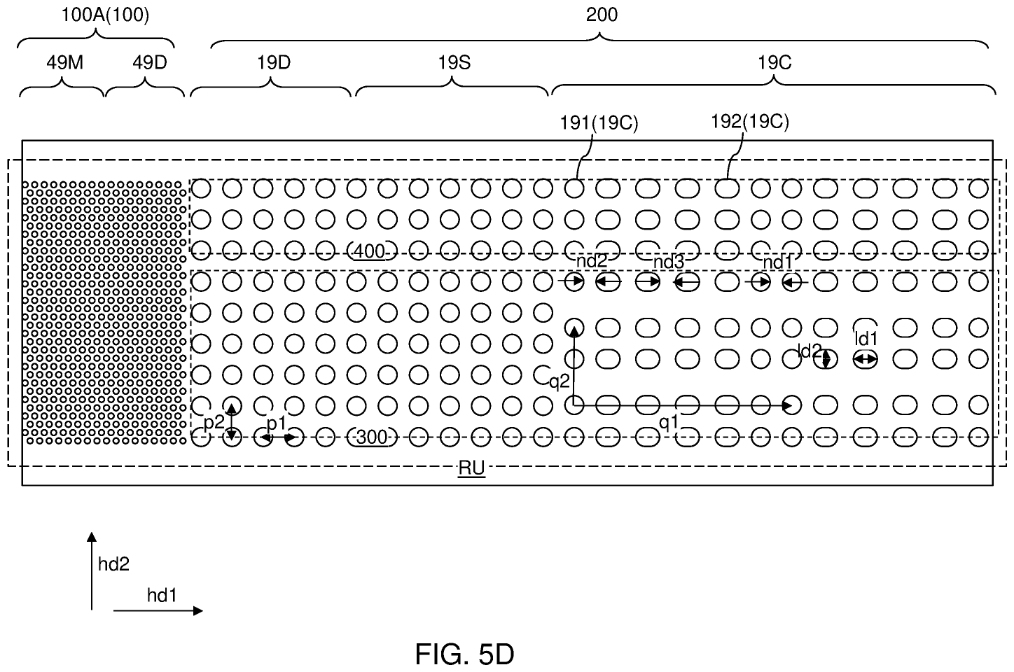

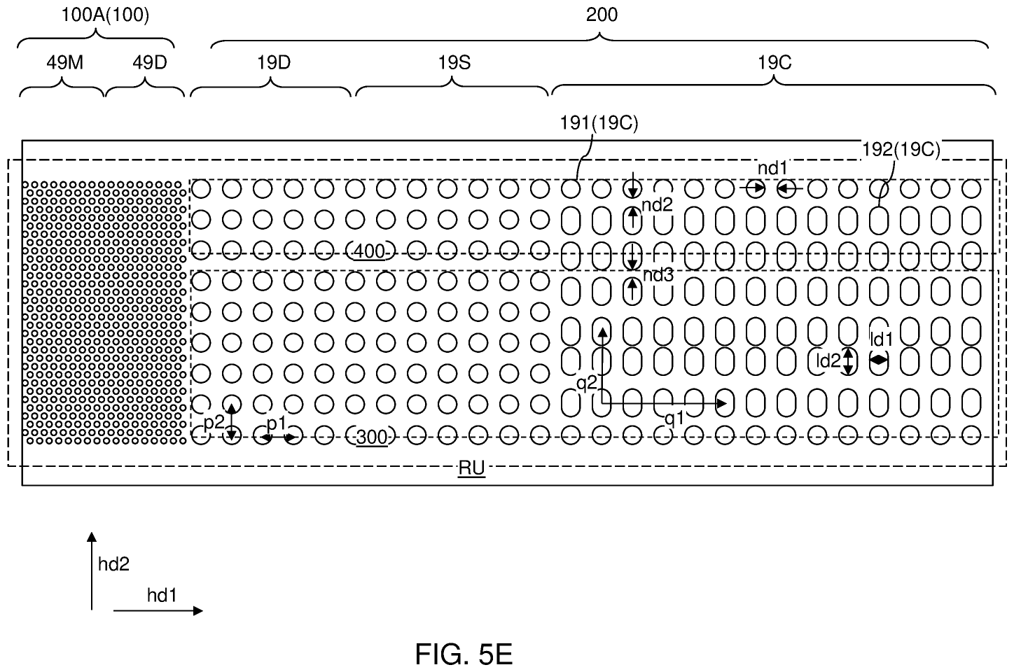

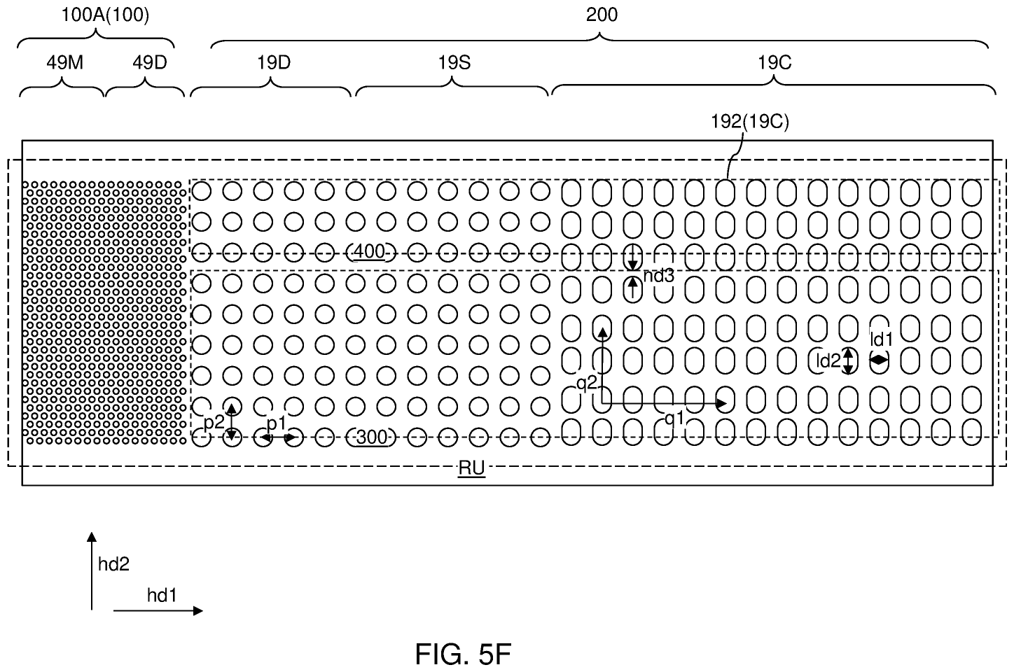

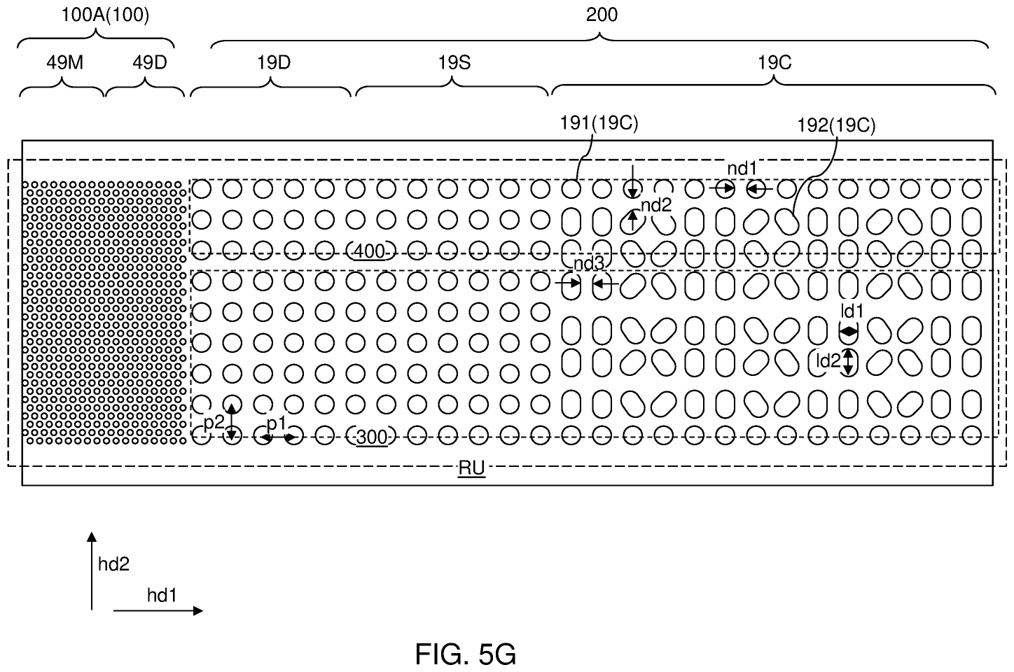

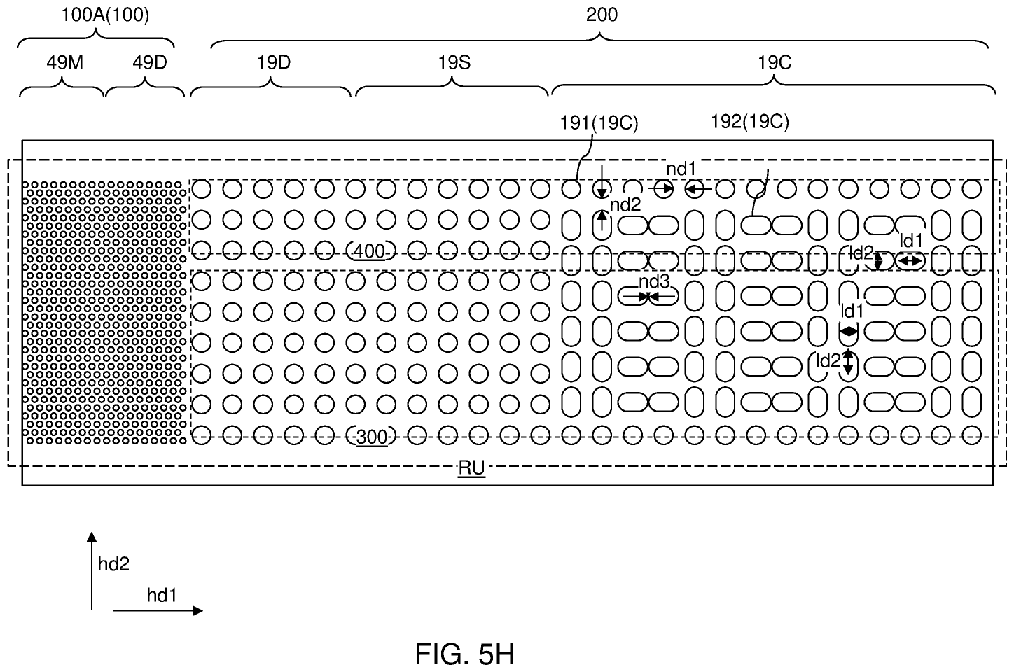

Referring to FIGS. 5A-5H, the exemplary structure is illustrated after formation of memory openings 49 and support openings 19. In one embodiment shown in FIG. 5A, the memory openings 49 include active memory openings 49M and optional dummy memory openings 49D, and the support openings 19 include dummy support openings 19D, primary support openings 19C and auxiliary support openings 19S. FIGS. 5B-5H are top-down views of various configurations of the exemplary structure of FIG. 5A. The areas illustrated in FIGS. 5B-5H corresponds to the area of region K illustrated in FIG. 4C.

The active memory openings 49M are formed within a respective memory array region 100A, and can be laterally spaced from the contact region 200 by dummy memory openings 49D. Active memory opening fill structures are subsequently formed in the active memory openings 49M, and are employed to store data therein. The dummy support openings 49D are formed in peripheral portions of the memory array regions 100 in proximity to a respective contact region 200. Dummy memory opening fill structures which do not store data are subsequently formed in the dummy memory openings 49D. The diameter of a top portion of each of the active memory openings 49M and the dummy memory openings 49D may be in a range from 50 nm to 200 nm, such as from 80 nm to 150 nm, although lesser and greater diameters may also be employed.

The dummy support openings 19D are formed in peripheral portions of the contact region 200 in proximity to the dummy memory openings 49D. The primary support openings 19C are formed in areas in which layer contact via structures are to be subsequently formed. The auxiliary support openings 19S are formed in areas in which drain-select-gate contact via structures are to be subsequently formed. In one embodiment, the auxiliary support openings 19S may be formed between the dummy support openings 19D and the primary support openings 19C. The auxiliary support openings 19S and the dummy support openings 19D may comprise cylindrical support openings having a respective circular horizontal cross-sectional shape. As used herein, a circular cross-sectional shape may have a horizontal shape of a circle or a slightly distorted circle due to inherent photolithography and etching variations.

The primary support openings 19C may comprise optional cylindrical support openings 191 having a respective circular horizontal cross-sectional shape, and laterally-elongated support openings 192 having a respective laterally-elongated horizontal cross-sectional shape. The diameter of a top portion of each of the cylindrical support openings 191, the auxiliary support openings 19S and the dummy support openings 19D may be in a range from 50 nm to 500 nm, such as from 100 nm to 300 nm, although lesser and greater diameters may also be employed.

Each laterally-elongated support opening 192 may have a first lateral dimension ld1 along the widthwise direction, and a second lateral dimension ld2 along the lengthwise direction, which is the lateral pillar elongation direction. Each of the laterally-elongated horizontal cross-sectional shapes of the laterally-elongated support opening 192 may have a length-to-width ratio in a range from 1.1 to 3, such as from 1.2 to 2. In other words, the ratio of the second lateral dimension ld2 to the first lateral dimension ld1 may be in a range from 1.1 to 3, such as from 1.2 to 2. A laterally-elongated horizontal cross-sectional shape may or may not include a pair of parallel sidewall segments. In one embodiment, a laterally-elongated horizontal cross-sectional shape may be a shape of an oval, such as an ellipse, which does not have parallel sidewall segments. Thus, in some embodiments, the laterally-elongated support openings 192 comprise laterally-elongated (i.e., non-circular oval) support openings 192 having an oval horizontal cross sectional shape. In one embodiment, the laterally-elongated oval support openings comprise laterally-elongated (i.e., non-circular) elliptical support openings 192 having a laterally-elongated elliptical horizontal cross sectional shape. The laterally-elongated elliptical support openings have two foci which are both not located at the center of the ellipse and minor and major axes which do not equal in length. The length of the minor axis of a top portion of each of the laterally-elongated elliptical support opening 192 may be in a range from 50 nm to 500 nm, such as from 100 nm to 300 nm, although lesser and greater lengths may also be employed, while the length of the major axis of a top portion of each of the laterally-elongated elliptical support opening 192 may be greater than the length of the minor axis, and may be in a range from 200 nm to 1,000 nm, such as from 400 nm to 600 nm, although lesser and greater lengths may also be employed,

The support openings (19D, 19S, 19C) may be formed in various configurations. In the first configuration and the second configuration illustrated in FIGS. 5B and 5C, respectively, areas that are free of support openings (19D, 19S, 19C) can be formed within the area of the primary support openings 19C. Each area that is free of support openings (19D, 19S, 19C) may comprise a center of an elongated hexagon that is laterally surrounded by a respective set of six hexagonally-arranged laterally-elongated support openings 192 that are located at six vertices of a respective elongated hexagon in a plan view. Each set of hexagonally-arranged laterally-elongated support openings 192 consists of six hexagonally-arranged laterally-elongated support openings 192 that are located at six vertices of an elongated hexagon in the plan view. Cylindrical support openings 191 are located between neighboring sets of hexagonally-arranged laterally-elongated support openings 192.

In the first configuration and the second configuration illustrated in FIGS. 5B and 5C, respectively, each of the hexagonally-arranged laterally-elongated support openings 192 has a maximum lateral dimension (e.g., a major axis for an elliptical opening) along a lateral pillar elongation direction that is greater than a diameter of each of the cylindrical support openings 191. In one embodiment, the diameter of each of the cylindrical support openings 191 may be the same as the width of each laterally-elongated support opening 192. Each elongated hexagon may be laterally elongated along a lateral hexagon elongation direction which is the same as the lateral pillar elongation direction. In the first configuration illustrated in FIG. 5B, the lateral hexagon elongation direction and the lateral pillar 192 elongation direction is the first horizontal direction (e.g., word line direction) hd1 along which the first memory array region 100A is laterally spaced from the second memory array region 100B. In the second configuration illustrated in FIG. 5C, the lateral hexagon elongation direction and the lateral pillar elongation direction is the second horizontal direction (e.g., bit line direction) hd2 which is perpendicular to the first horizontal direction hd1.

In one embodiment, each neighboring pair of cylindrical support openings 191 may be laterally spaced from each other by a first nearest neighbor distance nd1, which may be in a range from 50% to 200% of the diameter of the top portion of each cylindrical support opening 191. In one embodiment, each neighboring pair of a cylindrical support opening 191 and a laterally-elongated support opening 192 may be laterally spaced from each other by a second nearest neighbor distance nd2, which may be in a range from 50% to 200% of the diameter of the top portion of each cylindrical support opening 191. In one embodiment, each neighboring pair of laterally-elongated support openings 192 may be laterally spaced from each other by a third nearest neighbor distance nd3, which may be in a range from 50% to 200% of the diameter of the top portion of each cylindrical support opening 191. In one embodiment, the first nearest neighbor distance nd1, the second nearest neighbor distance nd2, and the third nearest neighbor distance nd3 may be the same.

In the first configuration and the second configuration illustrated in FIGS. 5B and 5C, respectively, each elongated hexagon having vertices located at geometrical centers of a set of six laterally-elongated support opening 192 may have a first side length a1 between a neighboring pair of vertices, and a second (i.e., elongated) side length a2 between another neighboring pair of vertices such that the second side length a2 is greater than the first side length a1. The direction of the second side length a2 may be parallel to the lateral pillar elongation direction as illustrated in FIG. 5B, or may be tilted relative to the lateral pillar elongation direction by an angle in a range from 15 degrees to 45 degrees as illustrated in FIG. 5C.

In one embodiment, a portion of the pattern of the primary support openings 19C may have a two-dimensional periodicity that is defined by a pair of displacement vectors q1 and q2, which includes a first displacement vector q1 and a second displacement vector q2. The first displacement vector q1 may be parallel to the first horizontal direction hd1. The second displacement vector q2 may be parallel to the second horizontal direction hd2, as shown in FIG. 5B, or may be non-parallel (e.g., offset by 15 to 45 degrees) to the second horizontal direction hd2, as shown in FIG. 5C.

The dummy support openings 19D and the auxiliary support openings 19S may or may not be arranged as a periodic two-dimensional array. In one embodiment, the dummy support openings 19D and the auxiliary support openings 19S may be arranged as a periodic two-dimensional array having a first periodicity p1 along the first horizontal direction hd1 and having a second periodicity p2 along the second horizontal direction hd2.

In the third, fourth, and fifth configurations illustrated in FIGS. 5D, 5E, and 5F, respectively, the laterally-elongated support openings 192 are laterally elongated along a lateral pillar elongation direction, and are arranged in multiple rows of laterally-elongated support openings 192 that laterally extend along the lateral pillar elongation direction. The lateral pillar elongation direction may be the first horizontal direction hd1 as illustrated in FIG. 5D, or may be the second horizontal direction hd2 as illustrated in FIGS. 5E and 5F.

In the third configuration illustrated in FIG. 5D, each row of laterally-elongated support openings 192 may be arranged along the first horizontal direction hd1 with a uniform pitch along the first horizontal direction hd1.

In the fourth and fifth configurations illustrated in FIGS. 5E and 5F, each row of laterally-elongated support openings 192 may be arranged along the second horizontal direction hd2. In one embodiment, nearest neighbor distances within each row of laterally-elongated support openings 192 may have a modulation along the lateral pillar elongation direction, such as the second horizontal direction hd2 as illustrated in FIGS. 5E and 5F. In one embodiment, multiple rows of laterally-elongated support openings 192 have a uniform row-to-row pitch along a horizontal direction that is perpendicular to the lateral pillar elongation direction (such as the first horizontal direction hd1) as illustrated in FIGS. 5E and 5F.

In one embodiment, widths of gaps between neighboring pairs of rows of laterally-elongated support openings 192 may have a modulation along the direction that is perpendicular to the lateral pillar elongation direction, as illustrated in FIG. 5E.

In one embodiment shown in FIG. 5E, the primary cylindrical support openings 191 may be located in the connection regions 400. Each of the laterally-elongated support openings 192 may have a maximum lateral dimension along the lateral pillar elongation direction that is greater than a diameter of each of the cylindrical dielectric pillar structures 191. In another embodiment shown in FIG. 5F, all primary support openings 19C comprise the laterally-elongated support openings 192, and there are no primary cylindrical support openings 191 may be located in the connection regions 400.

In the sixth and seventh configurations illustrated in FIGS. 5G and 5H, respectively, two types of laterally-elongated support openings 192 are provided. First laterally-elongated support openings 192 are laterally elongated along a first lateral pillar elongation direction, which may be, for example, the second horizontal direction hd2. The first laterally-elongated support openings 192 are arranged in multiple rows each laterally extending along a row direction that is the same as the first lateral pillar elongation direction. Second laterally-elongated support openings 192 are elongated along a respective lateral pillar elongation direction that is different from the first pillar elongation direction.

In one embodiment, each of the second laterally-elongated support openings 192 is elongated along a second lateral pillar elongation direction that is perpendicular to the first lateral pillar elongation direction (such as the first horizontal direction hd2). as illustrated in FIG. 5G.

In another embodiment, the second laterally-elongated support openings 192 are elongated along multiple lateral pillar elongation directions that is azimuthally offset the first lateral pillar elongation direction by a respective azimuthal angle in a range from −60 degrees to +60 degrees as illustrated in FIG. 5G.

In one embodiment, nearest neighbor distances within each row of first laterally-elongated support openings 192 have a modulation along the first lateral pillar elongation direction, as illustrated in FIG. 5G.

In one embodiment, the multiple rows of laterally-elongated support openings 192 have a uniform row-to-row pitch along a horizontal direction that is perpendicular to the first lateral pillar elongation direction (such as the first horizontal direction hd1), as illustrated in FIGS. 5G and 5H.

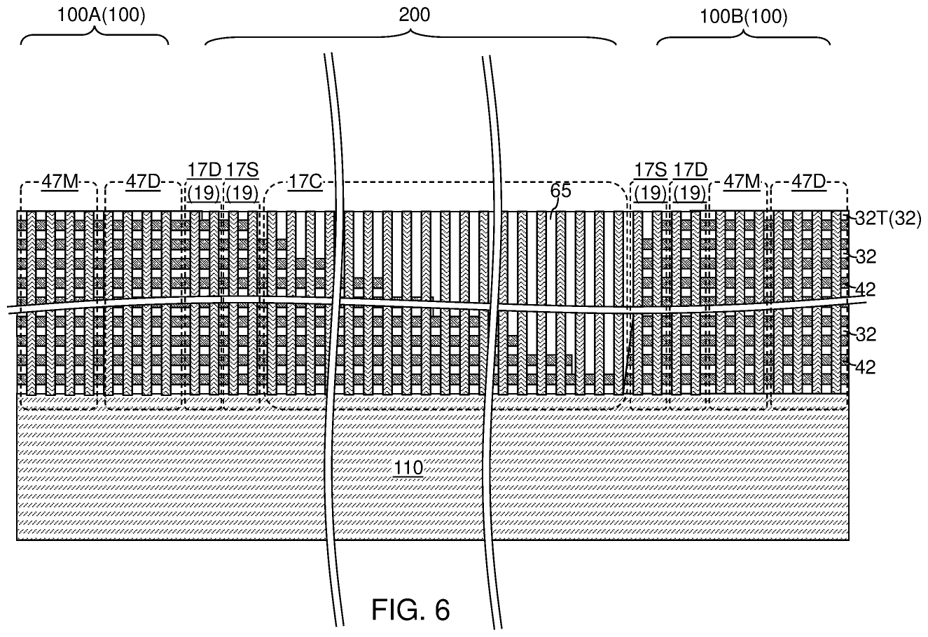

Referring to FIG. 6, a sacrificial fill material, such as amorphous carbon, can be deposited in each of the active memory openings 49M, the dummy memory openings 49D, and the support openings (19D, 19S, 19C). Excess portions of the sacrificial fill material can be removed from above the horizontal plane including the top surface of the topmost insulating layer 32T. Each active memory opening 49M is filled with a sacrificial memory opening fill material portion 47M. Each dummy memory opening 49D is filled with a sacrificial dummy memory opening fill material portion 47D. Each support opening (19D, 19S, 19C) is filled within a respective sacrificial support opening fill material portion (17D, 17S, 17C). Specifically, dummy sacrificial support opening fill material portion 17D is formed in each dummy support opening 19D, primary sacrificial support opening fill material portion 17C is formed in each primary support opening 19C, and auxiliary sacrificial support opening fill material portion 17S is formed in each auxiliary support opening 19S.

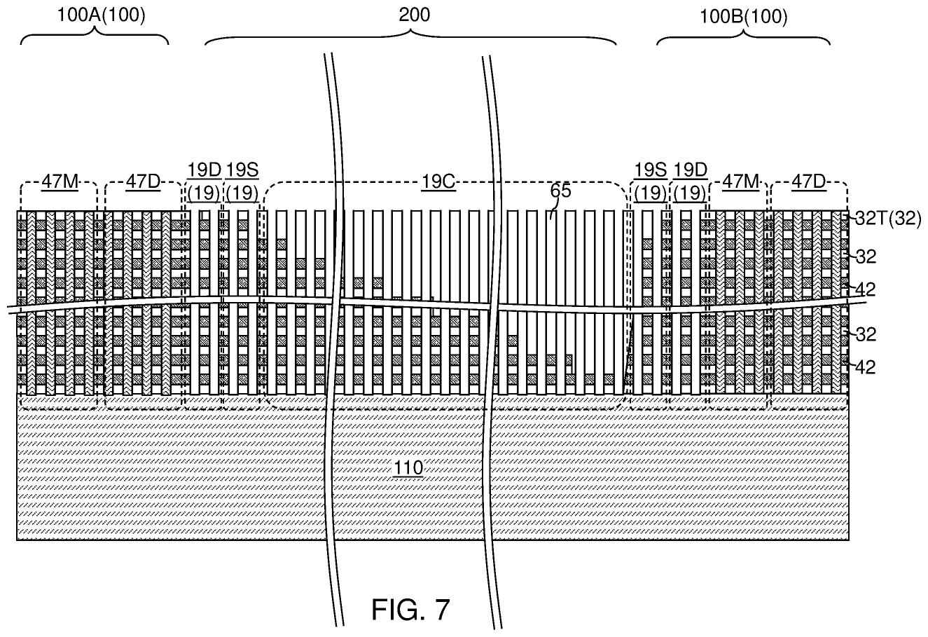

Referring to FIG. 7, a photoresist layer (not shown) can be applied over the exemplary structure, and can be lithographically patterned to cover the memory array regions 100 without covering the contact region 200. The sacrificial support opening fill material portions (17D, 17S, 17C) can be removed from inside the volumes of the support openings (19D, 19S, 19C). Cavities can be formed within the volumes of the support openings (19D, 19S, 19C).

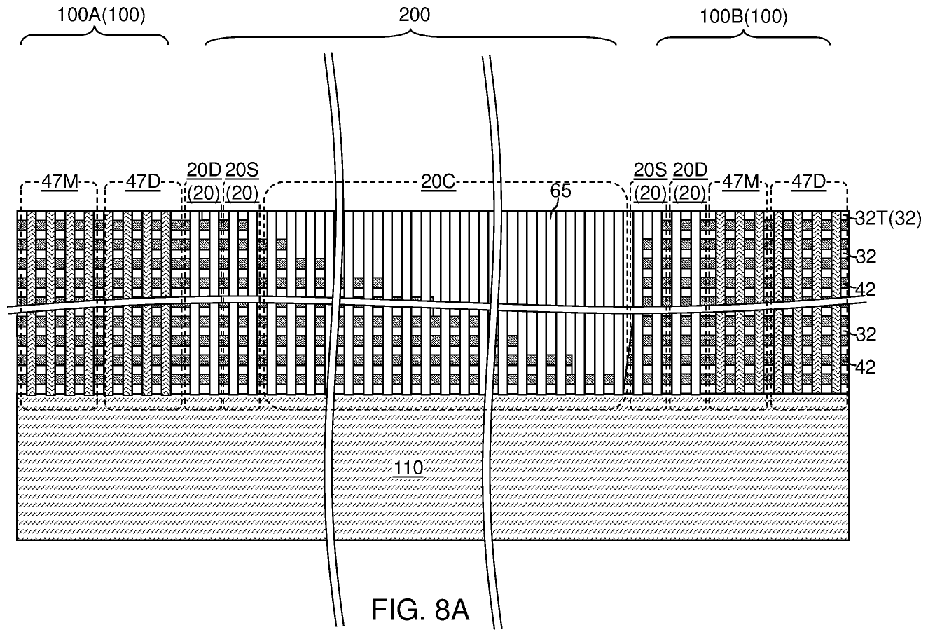

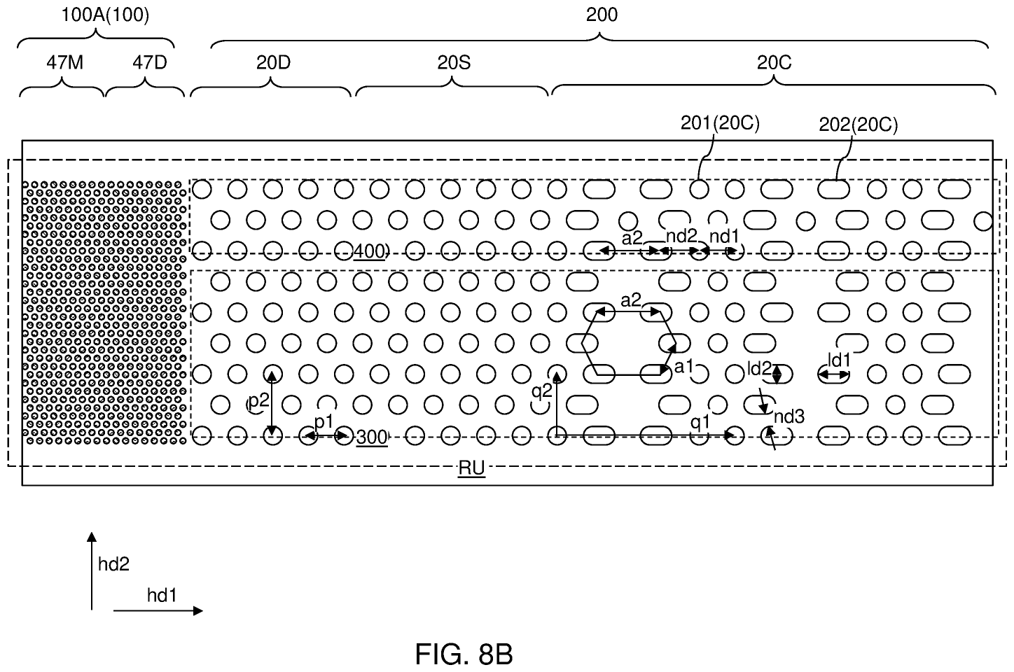

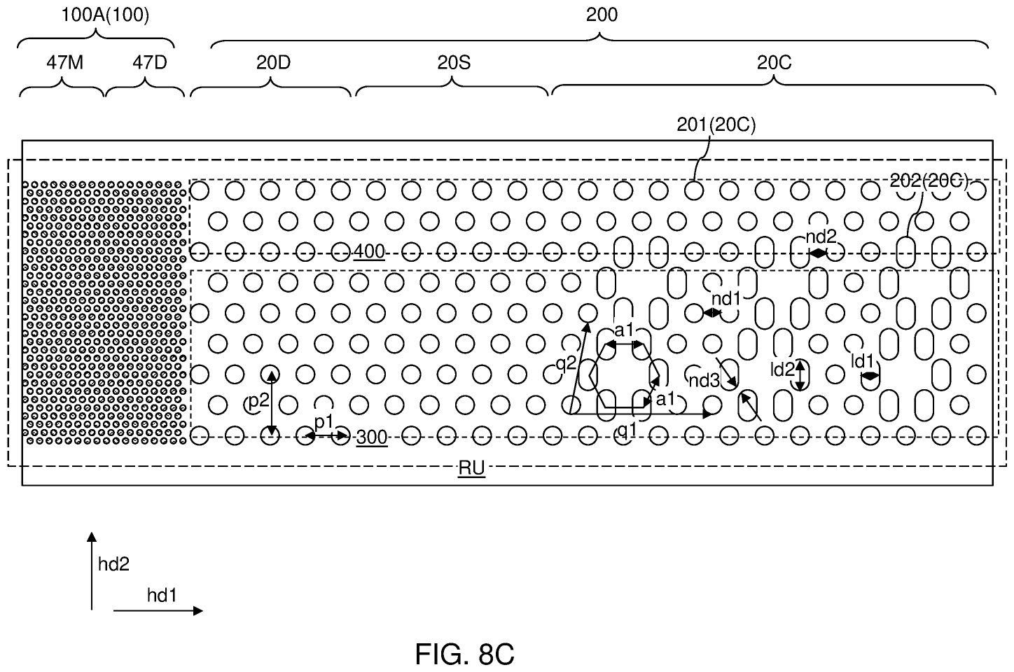

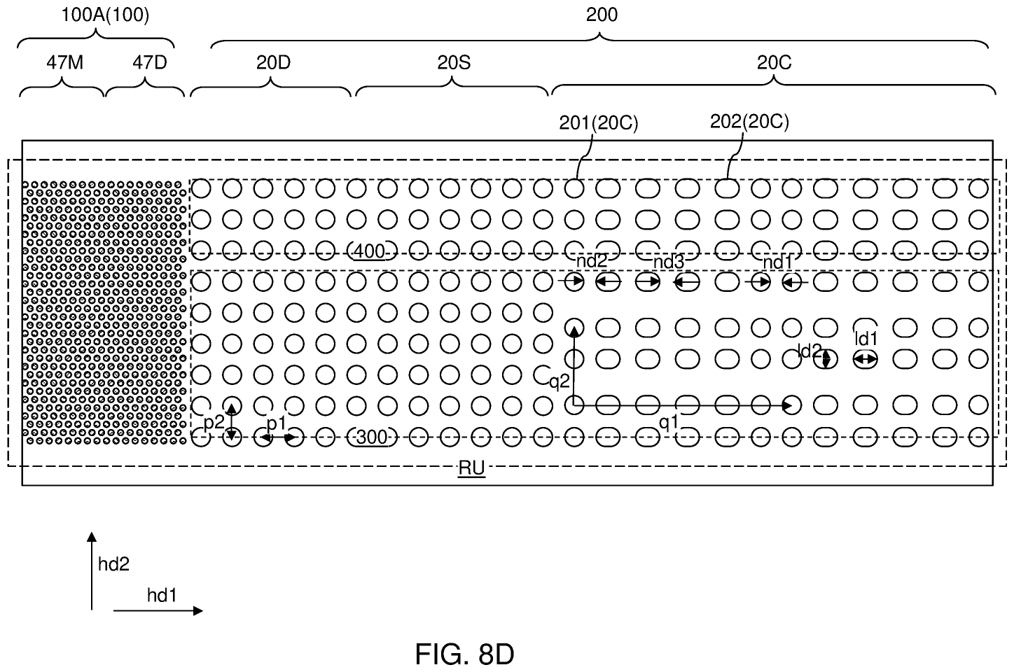

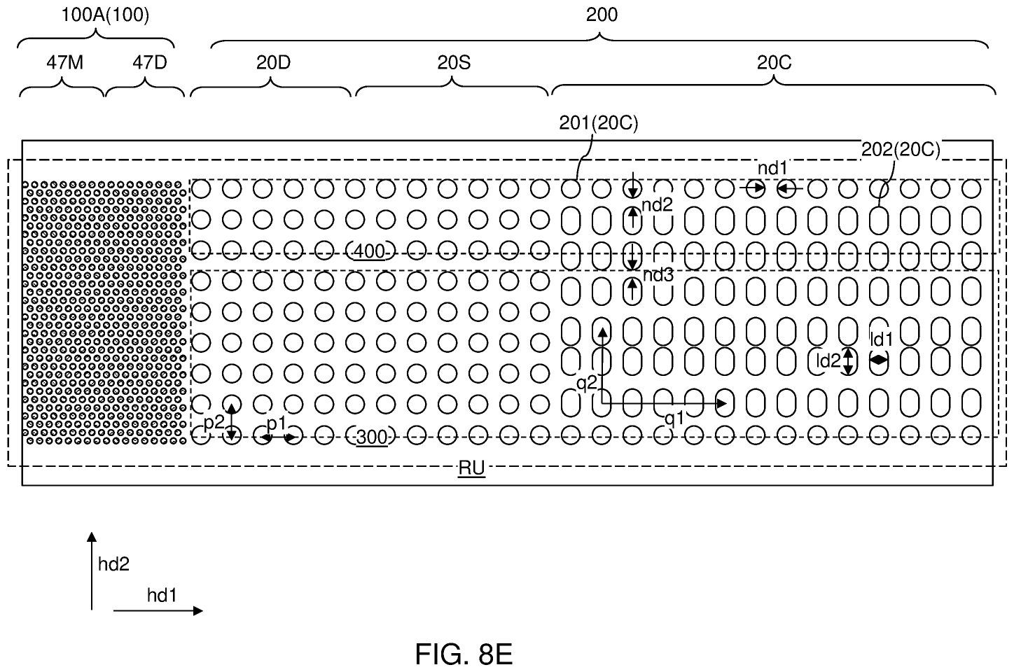

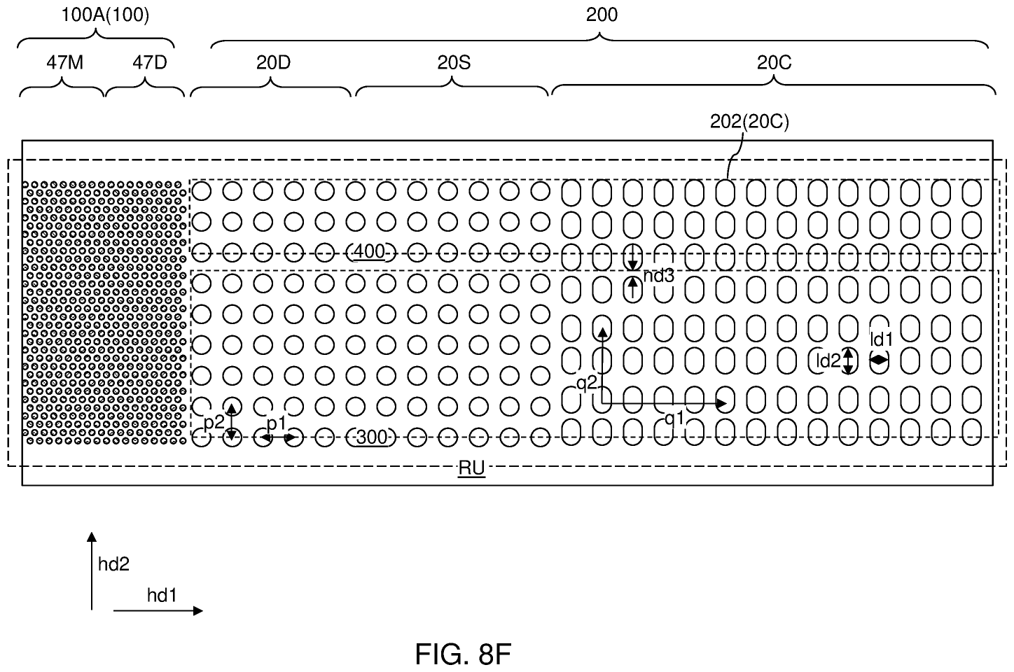

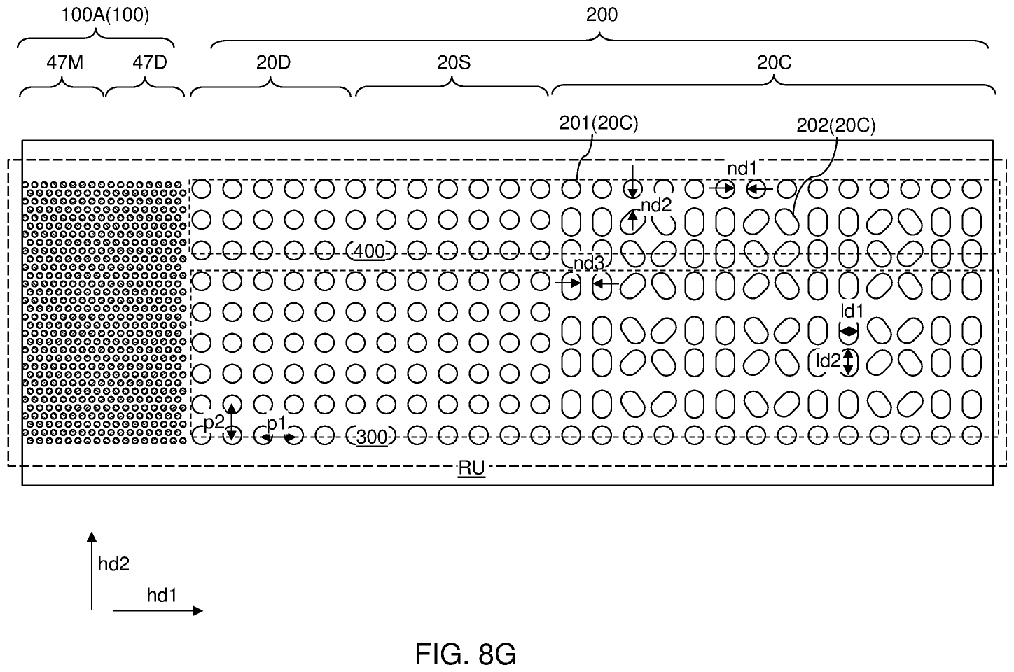

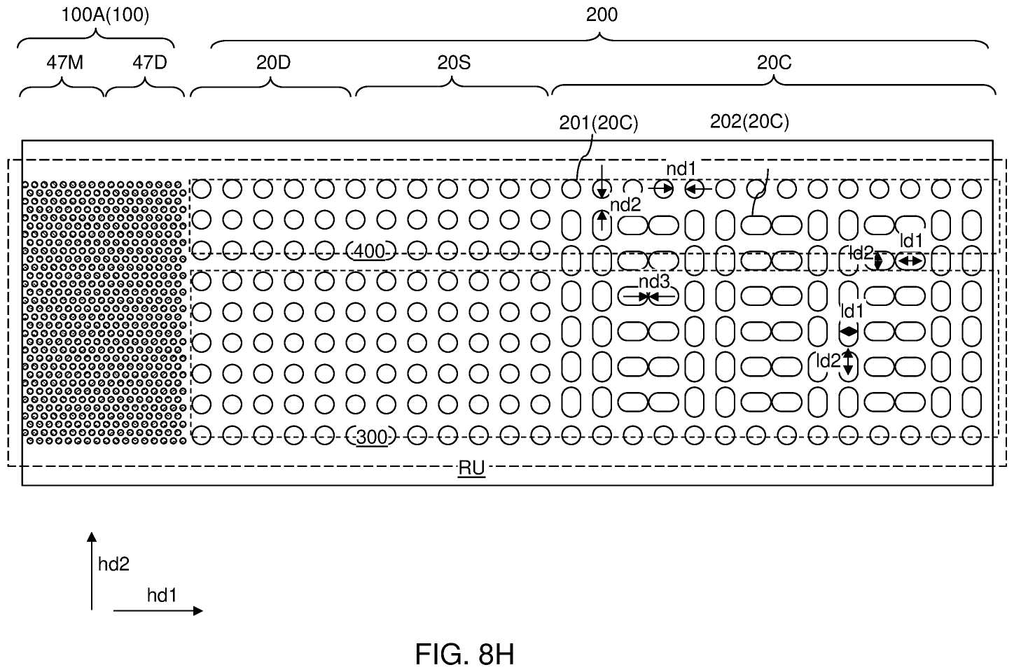

Referring to FIGS. 8A-8H, a dielectric fill material, such as silicon oxide, can be deposited in the support openings (19D, 19S, 19C), and excess portions of the dielectric fill material can be removed from above the horizontal plane including the top surface of the topmost insulating layer 32T by performing a planarization process. The planarization process may comprise a recess etch process or chemical mechanical polishing process. Each remaining portion of the dielectric fill material filling the support openings (19D, 19S, 19C) comprise dielectric pillar structures (20D, 20S, 20C), such as silicon oxide support pillar structures. Other insulating materials, such as silicon nitride, silicon oxynitride, or aluminum oxide, may be used instead.

The dielectric pillar structures (20D, 20S, 20C) may comprise dummy dielectric pillar structures 20D that are formed in dummy support openings 19D, primary dielectric pillar structures 20C that are formed in the primary support openings 19C, and auxiliary dielectric pillar structures 20S that are formed in the auxiliary support openings 19S. In one embodiment, the auxiliary dielectric pillar structures 20S may be formed between the dummy dielectric pillar structures 20D and the primary dielectric pillar structures 20C. In one embodiment, the dummy dielectric pillar structures 20D and the auxiliary dielectric pillar structures 20S may comprise cylindrical support pillar structures having a respective circular horizontal cross-sectional shape.

The primary dielectric pillar structures 20C may comprise optional cylindrical dielectric pillar structures 201 having a respective circular horizontal cross-sectional shape, and laterally-elongated dielectric pillar structures 202 having a respective laterally-elongated horizontal cross-sectional shape. The diameter of a top portion of each of the cylindrical dielectric pillar structures 201, the dummy dielectric pillar structures 20D and the auxiliary dielectric pillar structures 20S may be in a range from 50 nm to 500 nm, such as from 100 nm to 300 nm, although lesser and greater diameters may also be employed.

Each laterally-elongated dielectric pillar structure 202 may have a first lateral dimension ld1 along the widthwise direction, and a second lateral dimension ld2 along the lengthwise direction, which is the lateral pillar elongation direction. Each of the laterally-elongated horizontal cross-sectional shapes of the laterally-elongated dielectric pillar structure 202 may have a length-to-width ratio in a range from 1.1 to 3, such as from 1.2 to 2. In other words, the ratio of the second lateral dimension ld2 (e.g., the major axis of an elliptical shape) to the first lateral dimension ld1 (e.g., the minor axis of the elliptical shape) may be in a range from 1.1 to 3, such as from 1.2 to 2. A laterally-elongated horizontal cross-sectional shape may, or may not, include a pair of parallel sidewall segments. In one embodiment, a laterally-elongated horizontal cross-sectional shape may be a shape of an oval, such as an ellipse, which does not have parallel sidewall segments. Thus, in some embodiments, the laterally-elongated dielectric pillar structures 202 comprise laterally-elongated (i.e., non-circular oval) dielectric pillar structures 202 having an oval horizontal cross sectional shape. In one embodiment, the laterally-elongated oval dielectric pillar structures comprise laterally-elongated (i.e., non-circular) elliptical dielectric pillar structures 202 having a laterally-elongated elliptical horizontal cross sectional shape. The laterally-elongated elliptical dielectric pillar structures have two foci which are both not located at the center of the ellipse and minor and major axes which do not equal in length. The length of the minor axis of a top portion of each of the laterally-elongated elliptical dielectric pillar structure 202 may be in a range from 50 nm to 500 nm, such as from 100 nm to 300 nm, although lesser and greater lengths may also be employed, while the length of the major axis of a top portion of each of the laterally-elongated elliptical dielectric pillar structure 202 may be greater than the length of the minor axis, and may be in a range from 200 nm to 1,000 nm, such as from 400 nm to 600 nm, although lesser and greater lengths may also be employed.

The dielectric pillar structures (20D, 20S, 20C) may be formed in various configurations. In the first configuration and the second configuration illustrated in FIGS. 8B and 8C, respectively, areas that are free of dielectric pillar structures (20D, 20S, 20C) can be formed within the area of the primary dielectric pillar structures 20C. Each area that is free of dielectric pillar structures (20D, 20S, 20C) may comprise a center of an elongated hexagon that is laterally surrounded by a respective set of hexagonally-arranged laterally-elongated dielectric pillar structures 202 that are located at six vertices of a respective hexagon in a plan view. Each set of hexagonally-arranged laterally-elongated dielectric pillar structures 202 consists of six hexagonally-arranged laterally-elongated dielectric pillar structures 202 that are located at six vertices of an elongated hexagon in the plan view. Cylindrical dielectric pillar structures 201 are located between neighboring sets of hexagonally-arranged laterally-elongated dielectric pillar structures 202.

In the first configuration and the second configuration illustrated in FIGS. 8B and 8C, respectively, each of the hexagonally-arranged laterally-elongated dielectric pillar structures 202 has a maximum lateral dimension (e.g., a major axis for an elliptical dielectric pillar structure 201) along a lateral pillar elongation direction that is greater than a diameter of each of the cylindrical dielectric pillar structures 201. In one embodiment, the diameter of each of the cylindrical dielectric pillar structures 201 may be the same as the width of each laterally-elongated dielectric pillar structure 202. Each elongated hexagon may be laterally elongated along a lateral hexagon elongation direction which is the same as the lateral pillar elongation direction. In the first configuration illustrated in FIG. 8B, the lateral hexagon elongation direction and the lateral pillar elongation direction is the first horizontal direction hd1 along which the first memory array region 100A is laterally spaced from the second memory array region 100B. In the second configuration illustrated in FIG. 8C, the lateral hexagon elongation direction and the lateral pillar elongation direction is the second horizontal direction hd2 which is perpendicular to the first horizontal direction hd1.

In one embodiment, each neighboring pair of cylindrical dielectric pillar structures 201 may be laterally spaced from each other by a first nearest neighbor distance nd1, which may be in a range from 50% to 200% of the diameter of the top portion of each cylindrical dielectric pillar structure 201. In one embodiment, each neighboring pair of a cylindrical dielectric pillar structure 201 and a laterally-elongated dielectric pillar structure 202 may be laterally spaced from each other by a second nearest neighbor distance nd2, which may be in a range from 50% to 200% of the diameter of the top portion of each cylindrical dielectric pillar structure 201. In one embodiment, each neighboring pair of laterally-elongated dielectric pillar structures 202 may be laterally spaced from each other by a third nearest neighbor distance nd3, which may be in a range from 50% to 200% of the diameter of the top portion of each cylindrical dielectric pillar structure 201. In one embodiment, the first nearest neighbor distance nd1, the second nearest neighbor distance nd2, and the third nearest neighbor distance nd3 may be the same.

In the first configuration and the second configuration illustrated in FIGS. 8B and 8C, respectively, each elongated hexagon having vertices located at geometrical centers of a set of six laterally-elongated dielectric pillar structure 202 may have a first side length a1 between a neighboring pair of vertices, and a second (i.e., elongated) side length a2 between another neighboring pair of vertices such that the second side length a2 is greater than the first side length a1. The direction of the second side length a2 may be parallel to the lateral pillar elongation direction as illustrated in FIG. 8B, or may be tilted relative to the lateral pillar elongation direction by an angle in a range from 15 degrees to 45 degrees as illustrated in FIG. 8C.

In one embodiment, a portion of the pattern of the primary dielectric pillar structures 20C may have a two-dimensional periodicity that is defined by a pair of displacement vectors q1 and q2, which includes a first displacement vector q1 and a second displacement vector q2. The first displacement vector q1 may be parallel to the first horizontal direction hd1. The second displacement vector q2 may be parallel to the second horizontal direction hd2, as shown in FIG. 8B, or may be non-parallel (e.g., offset by 15 to 45 degrees) to the second horizontal direction hd2, as shown in FIG. 8C.

The dummy dielectric pillar structures 20D and the auxiliary dielectric pillar structures 20S may, or may not, be arranged as a periodic two-dimensional array. In one embodiment, the dummy dielectric pillar structures 20D and the auxiliary dielectric pillar structures 20S may be arranged as a periodic two-dimensional array having a first periodicity p1 along the first horizontal direction hd1 and having a second periodicity p2 along the second horizontal direction hd2.

In the third, fourth, and fifth configurations illustrated in FIGS. 8D, 8E, and 8F, respectively, the laterally-elongated dielectric pillar structures 202 are laterally elongated along a lateral pillar elongation direction, and are arranged in multiple rows of laterally-elongated dielectric pillar structures 202 that laterally extend along the lateral pillar elongation direction. The lateral pillar elongation direction may be the first horizontal direction hd1 as illustrated in FIG. 8D, or may be the second horizontal direction hd2 as illustrated in FIGS. 8E and 8F.

In the third configuration illustrated in FIG. 8D, each row of laterally-elongated dielectric pillar structures 202 may be arranged along the first horizontal direction hd1 with a uniform pitch along the first horizontal direction hd1.

In the fourth and fifth configurations illustrated in FIGS. 8E and 8F, each row of laterally-elongated dielectric pillar structures 202 may be arranged along the second horizontal direction hd2. In one embodiment, nearest neighbor distances within each row of laterally-elongated dielectric pillar structures 202 may have a modulation along the lateral pillar elongation direction such as the second horizontal direction hd2 as illustrated in FIGS. 8E and 8F. In one embodiment, multiple rows of laterally-elongated dielectric pillar structures 202 have a uniform row-to-row pitch along a horizontal direction that is perpendicular to the lateral pillar elongation direction (such as the first horizontal direction hd1) as illustrated in FIGS. 8E and 8F.

In one embodiment, widths of gaps between neighboring pairs of rows of laterally-elongated dielectric pillar structures 202 may have a modulation along the direction that is perpendicular to the lateral pillar elongation direction as illustrated in FIG. 8E.

In one embodiment, shown in FIG. 8E, the primary cylindrical dielectric pillar structures 201 may be located in the connection regions 400. Each of the laterally-elongated dielectric pillar structures 202 may have a maximum lateral dimension along the lateral pillar elongation direction that is greater than a diameter of each of the cylindrical dielectric pillar structures 201. In another embodiment shown in FIG. 8F, all primary dielectric pillar structures 20C comprise the laterally-elongated dielectric pillar structures 202, and there are no primary cylindrical dielectric pillar structures 201 may be located in the connection regions 400.

In the sixth and seventh configurations illustrated in FIGS. 8G and 8H, respectively, two types of laterally-elongated dielectric pillar structures 202 are provided. First laterally-elongated dielectric pillar structures 202 are laterally elongated along a first lateral pillar elongation direction, which may be, for example, the second horizontal direction hd2. The first laterally-elongated dielectric pillar structures 202 are arranged in multiple rows each laterally extending along a row direction that is the same as the first lateral pillar elongation direction. Second laterally-elongated dielectric pillar structures 202 are elongated along a respective lateral pillar elongation direction that is different from the first pillar elongation direction.

In one embodiment, each of the second laterally-elongated dielectric pillar structures 202 is elongated along a second lateral pillar elongation direction that is perpendicular to the first lateral pillar elongation direction (such as the first horizontal direction hd2) as illustrated in FIG. 8G.

In another embodiment, the second laterally-elongated dielectric pillar structures 202 are elongated along multiple lateral pillar elongation directions that is azimuthally offset the first lateral pillar elongation direction by a respective azimuthal angle in a range from −60 degrees to +60 degrees as illustrated in FIG. 8G.

In one embodiment, nearest neighbor distances within each row of first laterally-elongated dielectric pillar structures 202 have a modulation along the first lateral pillar elongation direction as illustrated in FIG. 8G.

In one embodiment, the multiple rows of laterally-elongated dielectric pillar structures 202 have a uniform row-to-row pitch along a horizontal direction that is perpendicular to the first lateral pillar elongation direction (such as the first horizontal direction hd1) as illustrated in FIGS. 8G and 8H.

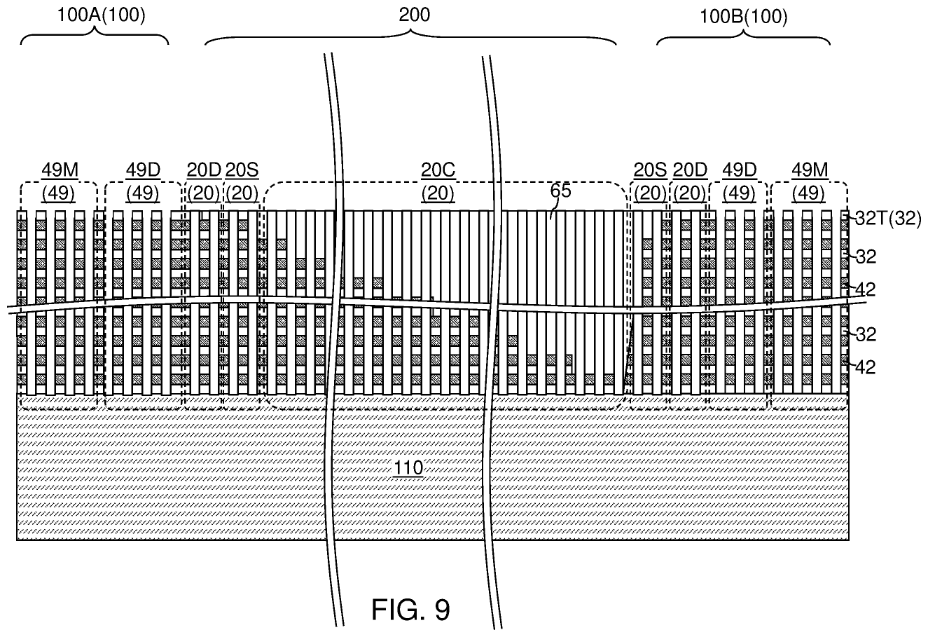

Referring to FIG. 9, the sacrificial memory opening fill material portions 47M and the sacrificial dummy memory opening fill material portions 47D can be removed, for example, by performing an ashing process. Voids are formed in the volumes of the active memory openings 49M and in the volumes of the dummy memory openings 49D.

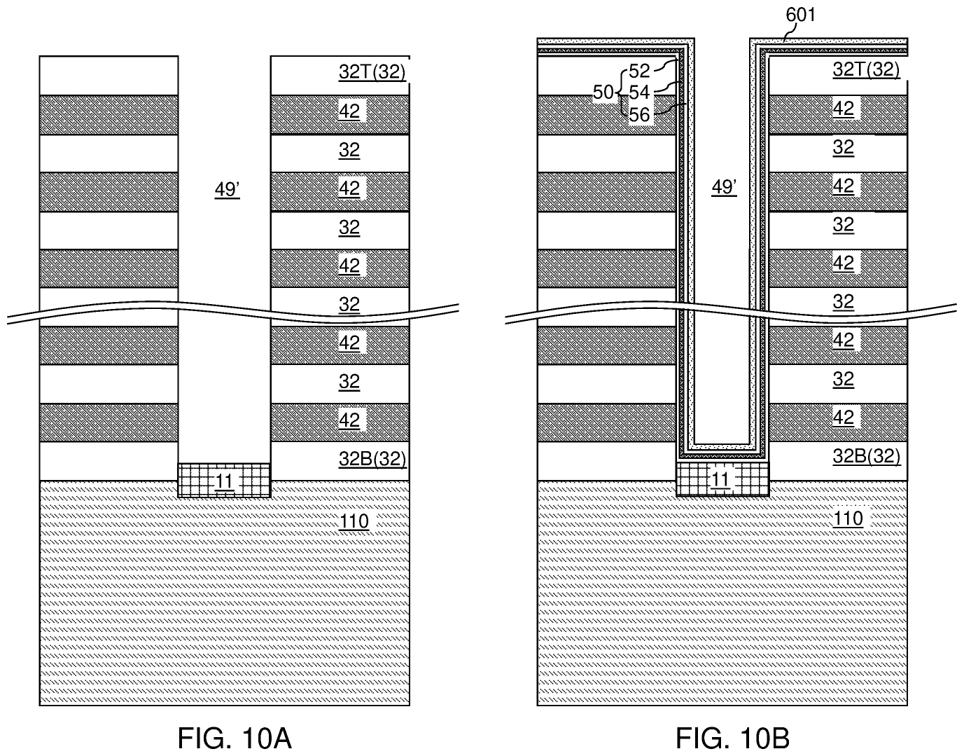

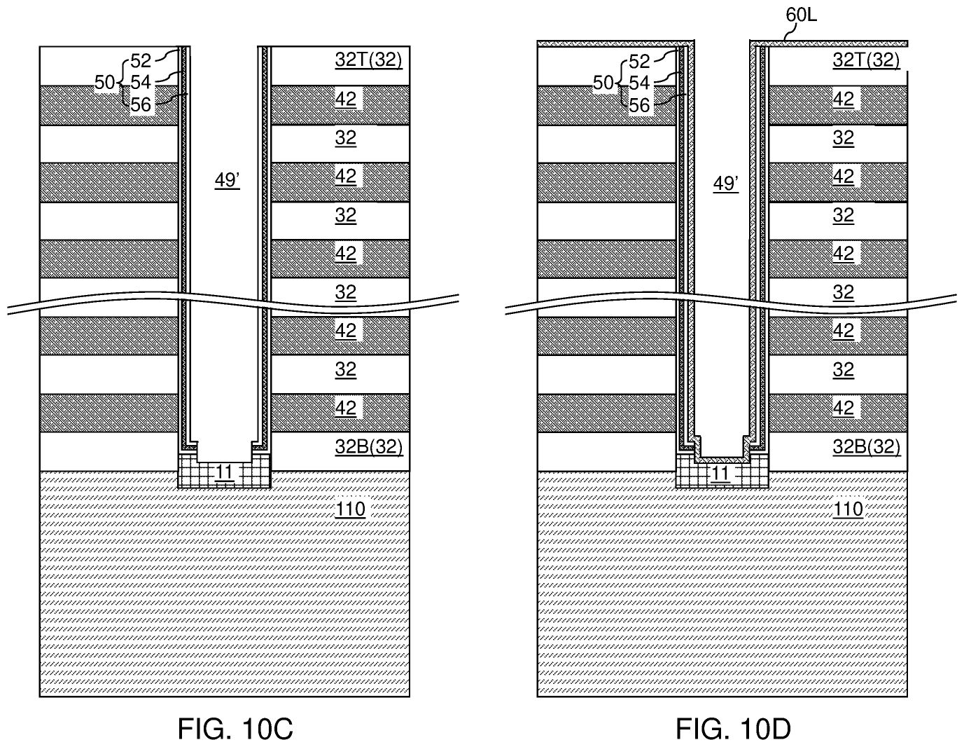

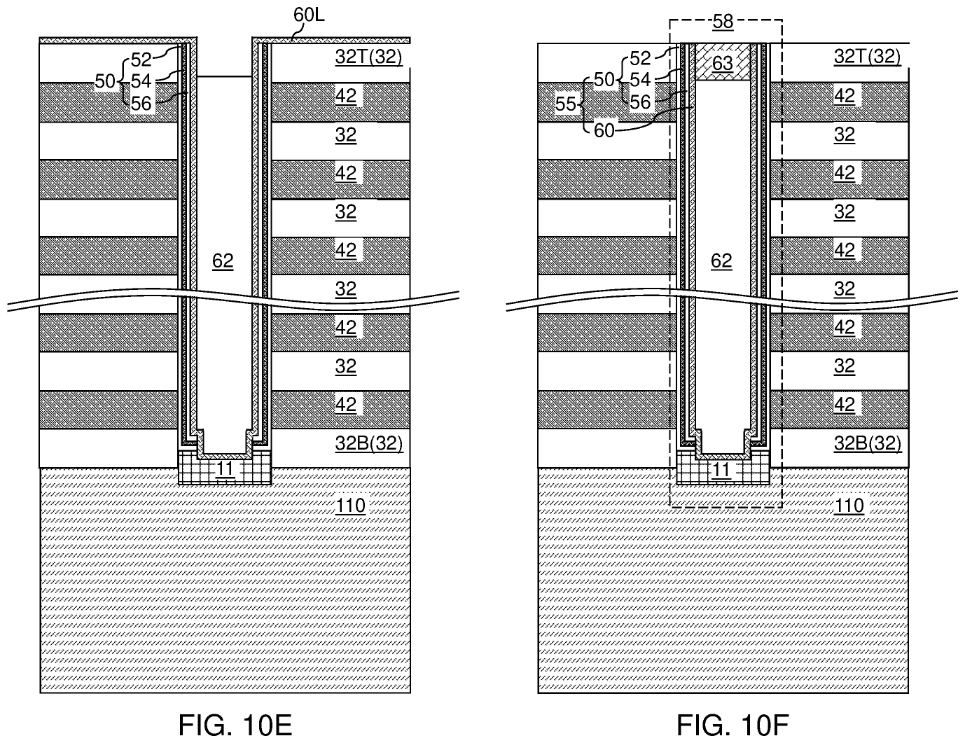

FIGS. 10A-10F are sequential vertical cross-sectional views of a region around a memory opening 49M during formation of a memory opening fill structure according to an embodiment of the present disclosure.

Referring to FIG. 10A, a memory opening 49M in the first exemplary structure of FIG. 9 is illustrated. The memory opening 49M extends through the alternating stack (32, 42), and into an upper portion of the semiconductor material layer 110. The recess depth of the bottom surface of each memory opening 49M with respect to the top surface of the semiconductor material layer 110 can be in a range from 0 nm to 30 nm, although greater recess depths can also be employed. Optionally, the sacrificial material layers 42 can be laterally recessed partially to form laterally-extending cavities (not shown), for example, by an isotropic etch.

An optional pedestal channel portion 11 (which may be a silicon pedestal) can be formed at the bottom portion of each memory opening 49M, for example, by a selective semiconductor deposition process. In one embodiment, the pedestal channel portion 11 can be doped with electrical dopants of the same conductivity type as the semiconductor material layer 110, which is a first conductivity type. In one embodiment, the top surface of each pedestal channel portion 11 can be formed below a horizontal plane including the top surface of the bottommost insulating layer 32B. The pedestal channel portion 11 can be a portion of a transistor channel that extends between a source region to be subsequently formed in the semiconductor material layer 110 and a drain region to be subsequently formed in an upper portion of the memory opening 49M. A memory cavity 49M′ is present in the unfilled portion of the memory opening 49M above the pedestal channel portion 11.

Referring to FIG. 10B, a stack of layers including a blocking dielectric layer 52, a memory material layer 54, and an optional dielectric liner 56 can be deposited in each memory opening 49M. The stack of layers is herein referred to as a memory film 50.

The blocking dielectric layer 52 can include a single dielectric material layer or a stack of a plurality of dielectric material layers. In one embodiment, the blocking dielectric layer 52 can include a dielectric metal oxide layer consisting essentially of a dielectric metal oxide. In one embodiment, the blocking dielectric layer 52 can include a dielectric metal oxide having a dielectric constant greater than 7.9, i.e., having a dielectric constant greater than the dielectric constant of silicon nitride. Alternatively or additionally, the blocking dielectric layer 52 can include a dielectric semiconductor compound such as silicon oxide, silicon oxynitride, silicon nitride, or a combination thereof. In one embodiment, the blocking dielectric layer 52 can include silicon oxide. In this case, the dielectric semiconductor compound of the blocking dielectric layer 52 can be formed by a conformal deposition method such as low pressure chemical vapor deposition, atomic layer deposition, or a combination thereof. The thickness of the dielectric semiconductor compound can be in a range from 1 nm to 20 nm, although lesser and greater thicknesses can also be employed.

The memory material layer 54 may comprise any memory material such as a charge storage material, a ferroelectric material, a phase change material, or any material that can store data bits in the form of presence or absence of electrical charges, a direction of ferroelectric polarization, electrical resistivity, or another measurable physical parameter. In one embodiment, the memory material layer 54 can be a continuous layer or patterned discrete portions of a charge trapping material including a dielectric charge trapping material, which can be, for example, silicon nitride. Alternatively, the memory material layer 54 can include a continuous layer or patterned discrete portions of a conductive material such as doped polysilicon or a metallic material that is patterned into multiple electrically isolated portions (e.g., floating gates), for example, by being formed within laterally-extending cavities into sacrificial material layers 42. In one embodiment, the memory material layer 54 includes a silicon nitride layer. In one embodiment, the sacrificial material layers 42 and the insulating layers 32 can have vertically coincident sidewalls, and the memory material layer 54 can be formed as a single continuous layer. Generally, the memory material layer 54 may comprise a vertical stack of memory elements that are located at levels of the sacrificial material layers 42. For example, the vertical stack of memory elements may be embodied as annular portions of the memory material layer 54 located at levels of the sacrificial material layers 42.

The optional dielectric liner 56, if present, comprises a dielectric liner material. In one embodiment, the dielectric liner 56 may comprise a tunneling dielectric layer through which charge tunneling can be performed under suitable electrical bias conditions. The charge tunneling may be performed through hot-carrier injection or by Fowler-Nordheim tunneling induced charge transfer depending on the mode of operation of the monolithic three-dimensional NAND string memory device to be formed. The dielectric liner 56 can include silicon oxide, silicon nitride, silicon oxynitride, dielectric metal oxides (such as aluminum oxide and hafnium oxide), dielectric metal oxynitride, dielectric metal silicates, alloys thereof, and/or combinations thereof. In one embodiment, the dielectric liner 56 can include a stack of a first silicon oxide layer, a silicon oxynitride layer, and a second silicon oxide layer, which is commonly known as an ONO stack. In one embodiment, the dielectric liner 56 can include a silicon oxide layer that is substantially free of carbon or a silicon oxynitride layer that is substantially free of carbon. The thickness of the dielectric liner 56 can be in a range from 2 nm to 20 nm, although lesser and greater thicknesses can also be employed.

Optionally, a sacrificial cover material layer 601 may be formed over the memory film 50.

Referring to FIG. 10C, the optional sacrificial cover material layer 601, the dielectric liner 56, the memory material layer 54, the blocking dielectric layer 52 are sequentially anisotropically etched employing at least one anisotropic etch process. The portions of the sacrificial cover material layer 601, the dielectric liner 56, the memory material layer 54, and the blocking dielectric layer 52 located above the top surface of the topmost insulating layer 32T can be removed by the at least one anisotropic etch process. Further, the horizontal portions of the sacrificial cover material layer 601, the dielectric liner 56, the memory material layer 54, and the blocking dielectric layer 52 at a bottom of each memory cavity 49M′ can be removed to form openings in remaining portions thereof. Each of the sacrificial cover material layer, the dielectric liner 56, the memory material layer 54, and the blocking dielectric layer 52 can be etched by a respective anisotropic etch process employing a respective etch chemistry, which may or may not be the same for the various material layers.

Each remaining portion of the sacrificial cover material layer 601, if employed, can have a tubular configuration. A surface of the pedestal channel portion 11 (or a surface of the semiconductor material layer 110 in case a pedestal channel portions 11 is not employed) can be physically exposed underneath the opening through the sacrificial cover material layer, the dielectric liner 56, the memory material layer 54, and the dielectric metal oxide blocking dielectric layer 52.

Optionally, the physically exposed semiconductor surface at the bottom of each memory cavity 49M′ can be vertically recessed so that the recessed semiconductor surface underneath the memory cavity 49M′ is vertically offset from the topmost surface of the pedestal channel portion 11 (or of the semiconductor material layer 110 in case pedestal channel portions 11 are not employed) by a recess distance. In one embodiment, the sacrificial cover material layer 601, the dielectric liner 56, the memory material layer 54, and the blocking dielectric layer 52 can have vertically coincident sidewalls. The sacrificial cover material layer 601 can be subsequently removed selective to the material of the dielectric liner 56.

In case the sacrificial cover material layer 601 includes amorphous silicon, a wet etch process employing hot trimethyl-2 hydroxyethyl ammonium hydroxide (“hot TMY”) or tetramethyl ammonium hydroxide (TMAH) can be performed to remove the sacrificial cover material layer. Alternatively, the sacrificial cover material layer 601 may be retained in the final device if it comprises a silicon material.

Referring to FIG. 10D, a semiconductor channel layer 60L can be deposited directly on the semiconductor surface of the pedestal channel portion 11 or the semiconductor material layer 110 if the pedestal channel portion 11 is omitted, and directly on the memory film 50. The semiconductor channel layer 60L includes a semiconductor material such as at least one elemental semiconductor material, at least one III-V compound semiconductor material, at least one II-VI compound semiconductor material, at least one organic semiconductor material, or other semiconductor materials known in the art. In one embodiment, the semiconductor channel layer 60L includes amorphous silicon or polysilicon. The semiconductor channel layer 60L can have a doping of a first conductivity type, which is the same as the conductivity type of the semiconductor material layer 110 and the pedestal channel portions 11. The semiconductor channel layer 60L can be formed by a conformal deposition method such as low pressure chemical vapor deposition (LPCVD). The thickness of the semiconductor channel layer 60L can be in a range from 2 nm to 10 nm, although lesser and greater thicknesses can also be employed. The semiconductor channel layer 60L may partially fill the memory cavity 49M′ in each memory opening, or may fully fill the cavity in each memory opening.

Referring to FIG. 10E, a dielectric core layer can be deposited to fill any remaining portion of the memory cavity 49M′ within each memory opening 49M. The dielectric core layer includes a dielectric material such as silicon oxide or organosilicate glass. The dielectric core layer can be deposited by a conformal deposition method such as low pressure chemical vapor deposition (LPCVD), or by a self-planarizing deposition process such as spin coating.

The horizontal portion of the dielectric core layer can be removed, for example, by a recess etch process such that each remaining portions of the dielectric core layer is located within a respective memory opening 49M and has a respective top surface below the horizontal plane including the top surface of the topmost insulating layer 32T. Each remaining portion of the dielectric core layer constitutes a dielectric core 62.

Referring to FIG. 10F, a doped semiconductor material having a doping of a second conductivity type can be deposited within each recessed region above the dielectric cores 62. The deposited semiconductor material can have a doping of a second conductivity type that is the opposite of the first conductivity type. For example, if the first conductivity type is p-type, the second conductivity type is n-type, and vice versa. The dopant concentration in the deposited semiconductor material can be in a range from 5.0×10¹⁸/cm³ to 2.0×10²¹/cm³, although lesser and greater dopant concentrations can also be employed. The doped semiconductor material can be, for example, doped polysilicon.

Excess portions of the deposited semiconductor material having a doping of the second conductivity type and a horizontal portion of the semiconductor channel layer 60L can be removed from above the horizontal plane including the top surface of the topmost insulating layer 32T, for example, by chemical mechanical planarization (CMP) or a recess etch process. Each remaining portion of the doped semiconductor material having a doping of the second conductivity type constitutes a drain region 63. Each remaining portion of the semiconductor channel layer 60L (which has a doping of the first conductivity type) constitutes a vertical semiconductor channel 60.

Each combination of a memory film 50 and a vertical semiconductor channel 60 within a memory opening 49M constitutes a memory stack structure 55. The memory stack structure 55 is a combination of a vertical semiconductor channel 60, an optional dielectric liner 56, a plurality of memory elements comprising portions of the memory material layer 54, and an optional blocking dielectric layer 52. Each combination of a pedestal channel portion 11 (if present), a memory stack structure 55, a dielectric core 62, and a drain region 63 within a memory opening 49M is herein referred to as a memory opening fill structure 58.

The memory opening fill structures 58 may comprise active memory opening fill structures 58M that are formed in the active memory openings 49M, and dummy memory opening fill structures 58D that are formed in the dummy memory openings 49D. Generally, first active memory openings 49M and second active memory openings 49M may vertically extend through the alternating stack (32, 42) in the first memory array region 100A and in the second memory array region 100B, respectively. First active memory opening fill structures 58M and second active memory opening fill structures 58M may be formed in the first active memory openings 49M and in the second active memory openings 49M, respectively. Each of the first active memory opening fill structures 58M and second active memory opening fill structures 58M comprises a respective vertical stack of memory elements, which comprise portions of the memory film 50, and a vertical semiconductor channel 60. The active memory opening fill structures 58M are used to store data, while the dummy memory opening fill structures 58D are not used to store data.

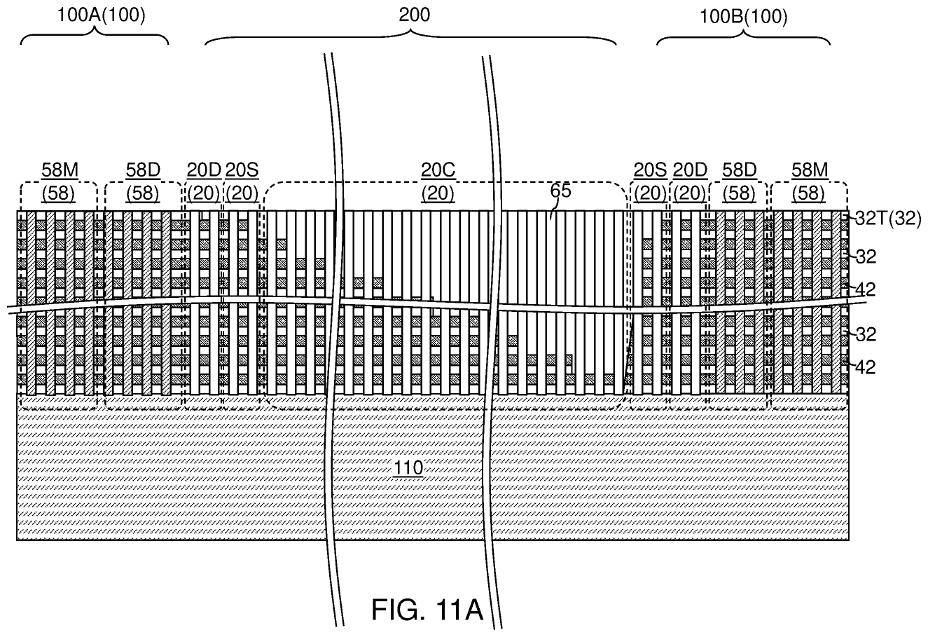

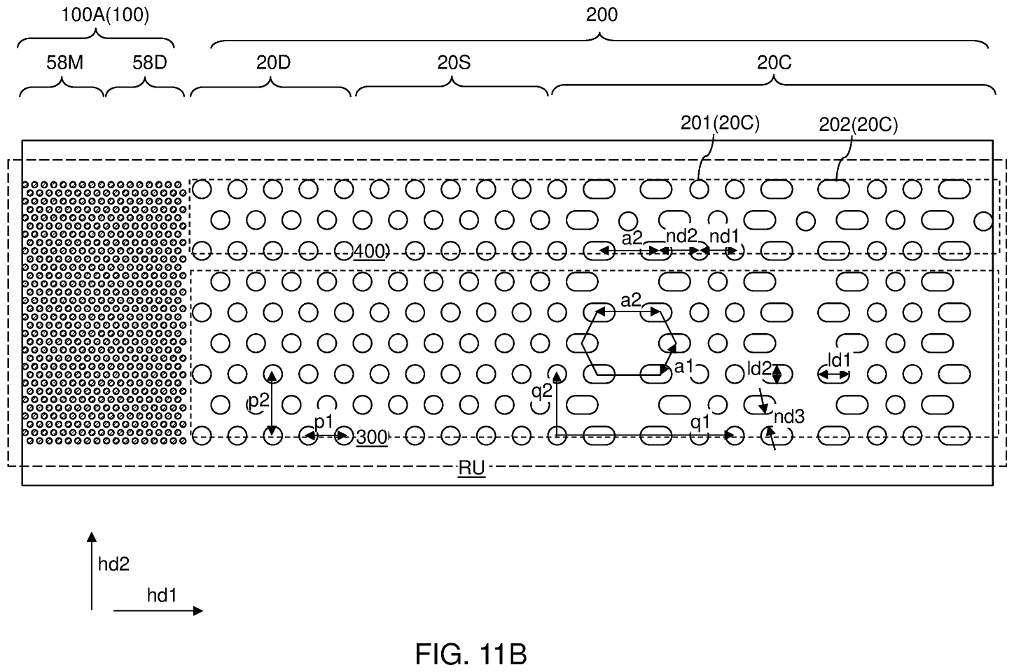

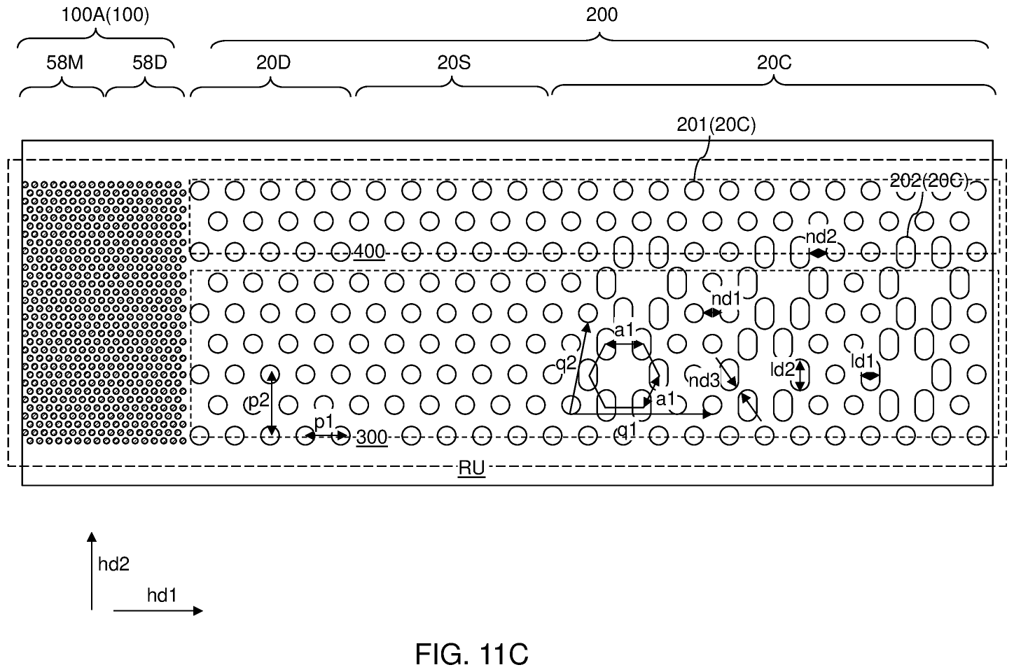

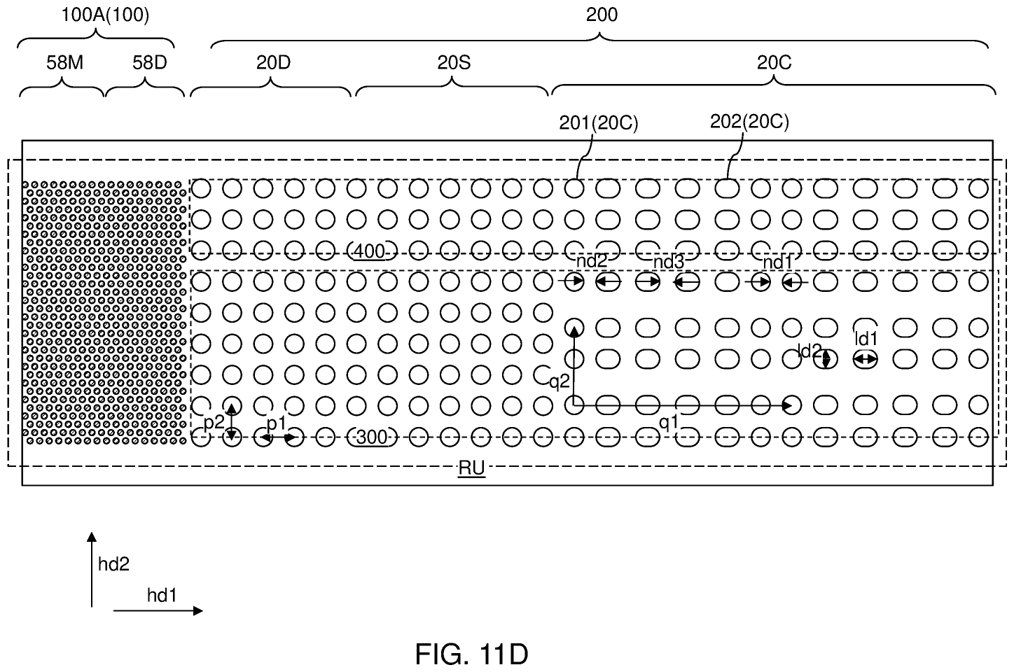

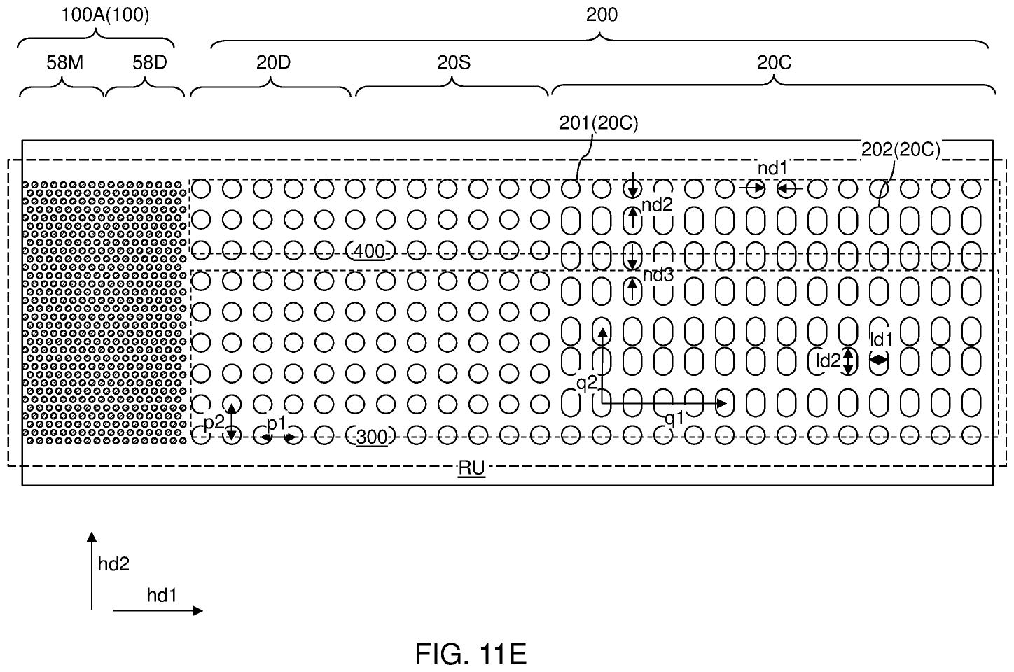

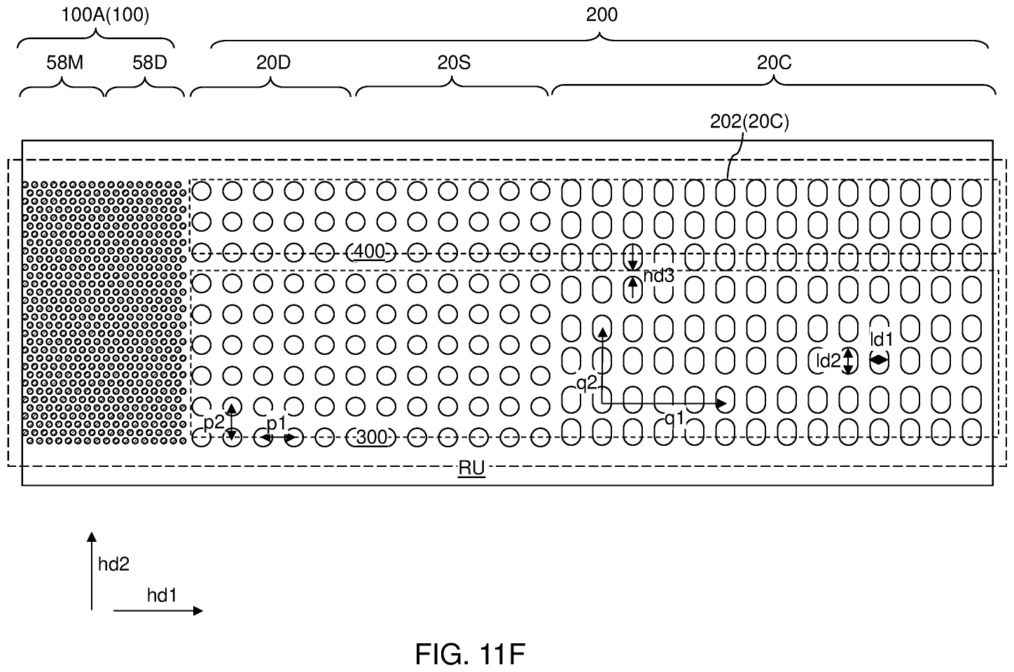

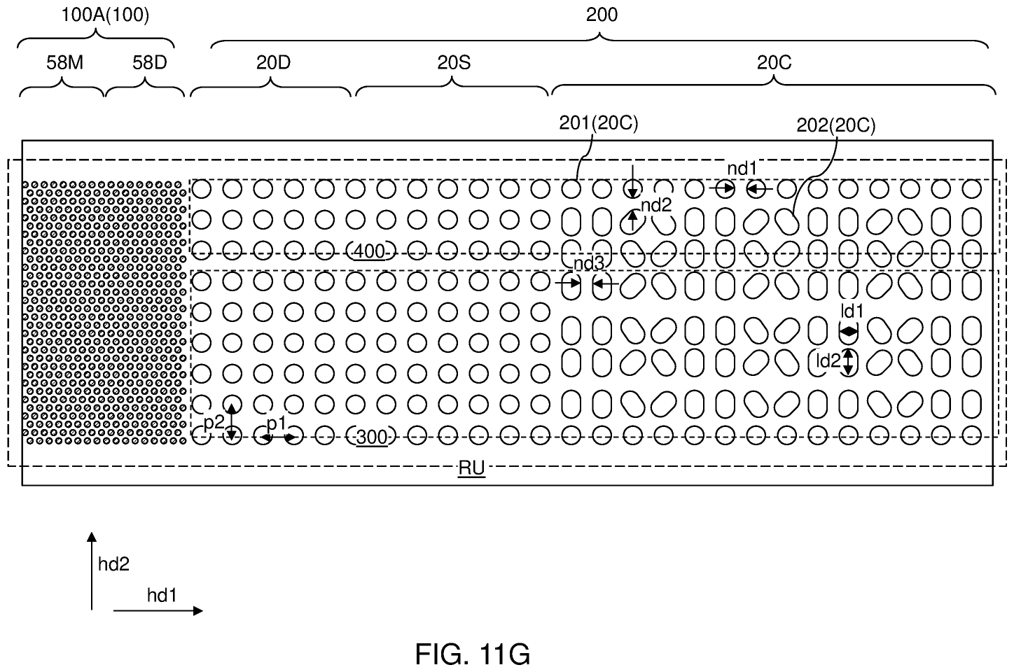

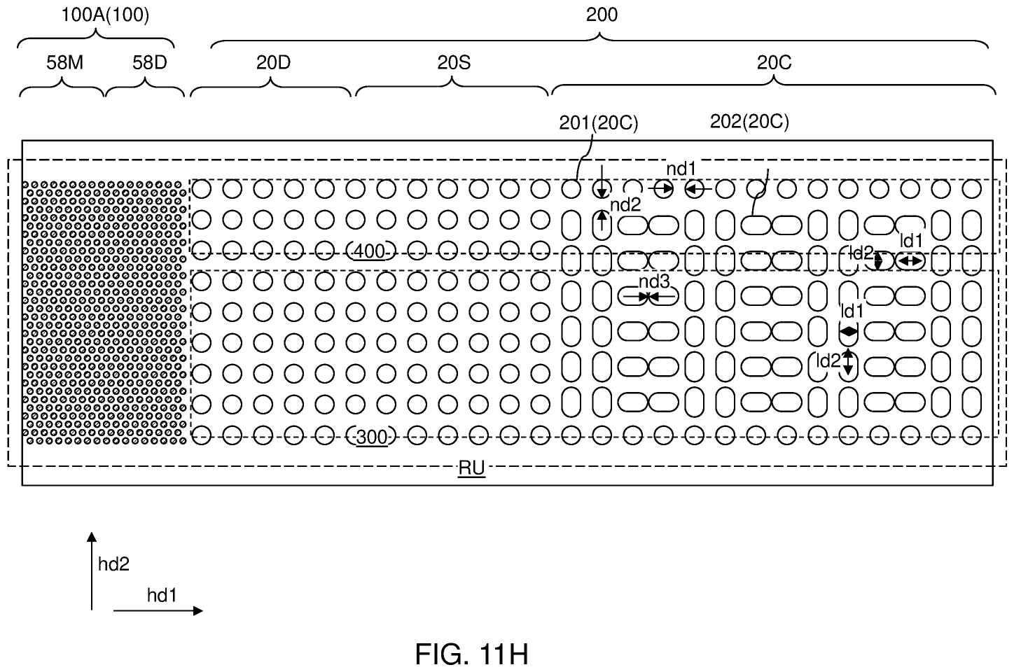

FIG. 11A is a vertical cross-sectional view of the exemplary structure after formation of memory opening fill structures 58 according to an embodiment of the present disclosure. FIGS. 11B-11H are top-down views of various configurations of the exemplary structure of FIG. 11A.

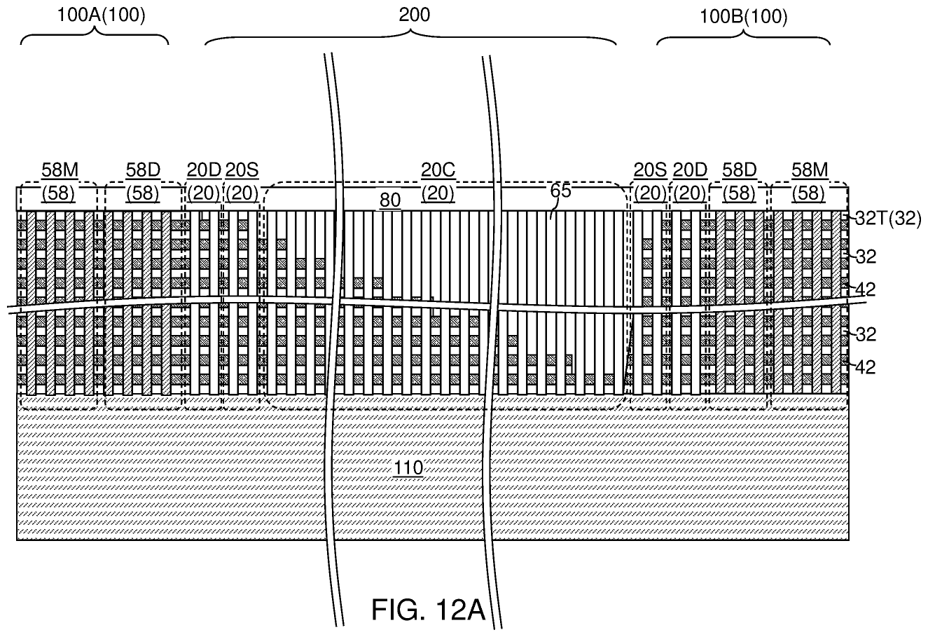

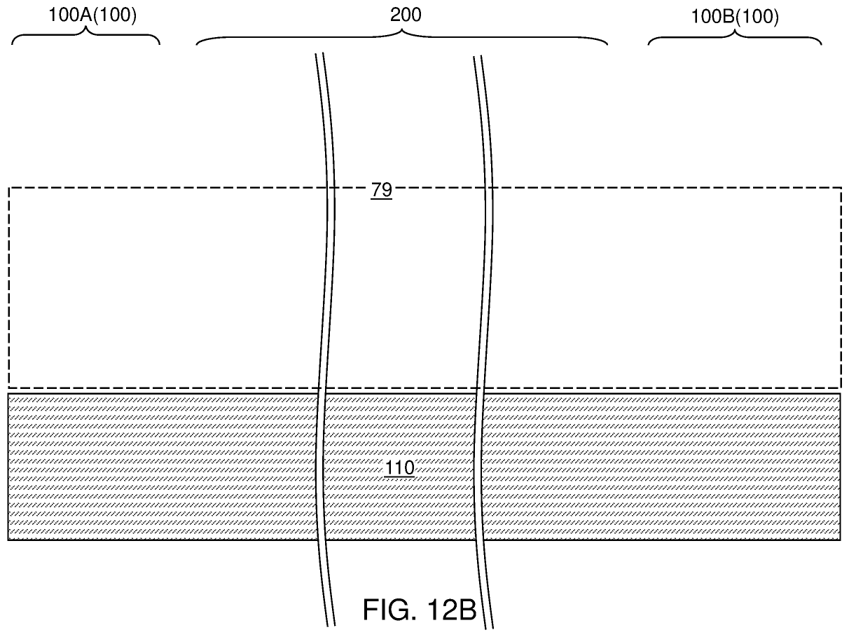

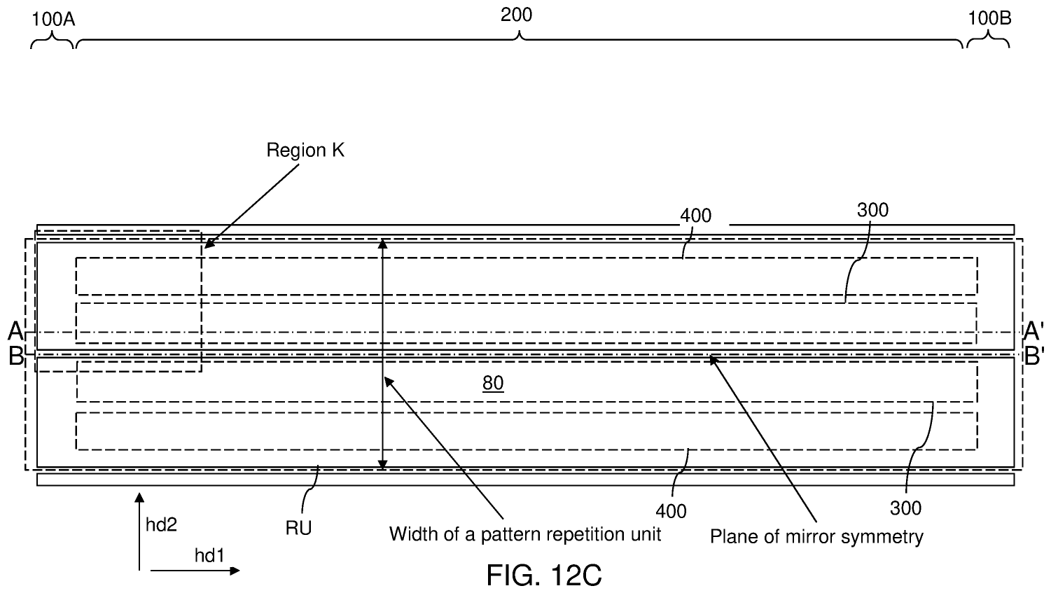

Referring to FIGS. 12A-12C, a dielectric material can be deposited above the alternating stack (32, 42) and the retro-stepped dielectric material portions 65 to form a contact-level dielectric layer 80. A photoresist layer (not shown) can be applied over the contact-level dielectric layer 80, and can be lithographically patterned to form elongated openings that laterally extend along the first horizontal direction hd1 with a uniform width along the second horizontal direction hd2. An anisotropic etch process can be performed to transfer the pattern of the elongated openings in the photoresist layer through the contact-level dielectric layer 80, the alternating stack (32, 42), and the retro-stepped dielectric material portions 65. Lateral isolation trenches 79 are formed in the volumes from which the materials of the contact-level dielectric layer 80, the alternating stack (32, 42), and the retro-stepped dielectric material portions 65 are removed.

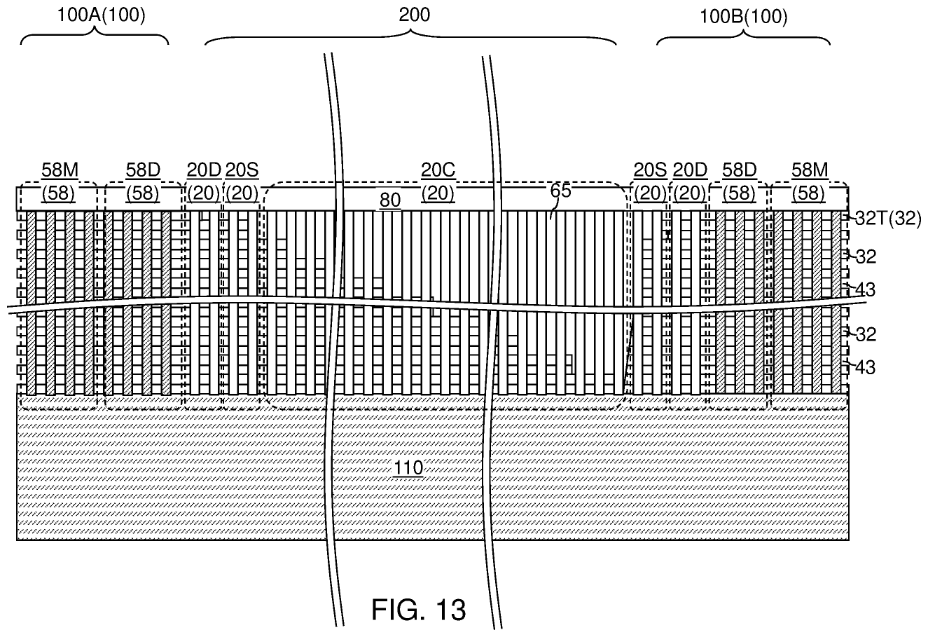

Referring to FIG. 13, an isotropic etch process can be performed to introduce an isotropic etchant that etches a material of the sacrificial material layers 42 into the lateral isolation trenches 79. For example, if the sacrificial material layers 42 comprise silicon nitride, the isotropic etch process may comprise a wet etch process employing hot phosphoric acid. Laterally-extending cavities 43 are formed in volumes from which portions of the sacrificial material layers 42 are removed by the isotropic etch process.

Referring to FIGS. 14A-14C, a backside blocking dielectric layer (not shown) may be optionally deposited in the laterally-extending cavities 43 on the physically exposed surfaces of the retro-stepped dielectric material portions 65, the memory opening fill structures 58, and the insulating layers 32 by a conformal deposition process. At least one conductive material can be deposited in unfilled volumes of the laterally-extending cavities and in the volumes of the lateral recess cavities by providing at least one reactant gas into the laterally-extending cavities and into the lateral recess cavities through the lateral isolation trenches. For example, the at least one conductive material may comprise a metallic barrier layer and a metallic fill material.

The metallic barrier layer includes an electrically conductive metallic material that can function as a diffusion barrier layer and/or adhesion promotion layer for a metallic fill material to be subsequently deposited. The metallic barrier layer can include a conductive metallic nitride material such as TiN, TaN, WN, or a stack thereof, or can include a conductive metallic carbide material such as TiC, TaC, WC, or a stack thereof. In one embodiment, the metallic barrier layer can be deposited by a conformal deposition process such as chemical vapor deposition (CVD) or atomic layer deposition (ALD). The thickness of the metallic barrier layer can be in a range from 2 nm to 8 nm, such as from 3 nm to 6 nm, although lesser and greater thicknesses can also be employed. In one embodiment, the metallic barrier layer can consist essentially of a conductive metal nitride such as TiN.

The metal fill material can be deposited over the metallic barrier layer to form a metallic fill material layer. The metallic fill material can be deposited by a conformal deposition method, which can be, for example, chemical vapor deposition (CVD), atomic layer deposition (ALD), electroless plating, electroplating, or a combination thereof. In one embodiment, the metallic fill material layer can consist essentially of at least one elemental metal. The at least one elemental metal of the metallic fill material layer can be selected, for example, from tungsten, cobalt, ruthenium, titanium, and tantalum. In one embodiment, the metallic fill material layer can consist essentially of a single elemental metal. In one embodiment, the metallic fill material layer can be deposited employing a fluorine-containing precursor gas, such as WF₆. In one embodiment, the metallic fill material layer can be a tungsten layer including a residual level of fluorine atoms as impurities. The metallic fill material layer is spaced from the insulating layers 32 and the memory opening fill structures 58 by the metallic barrier layer, which is a metallic barrier layer that blocks diffusion of fluorine atoms therethrough.

A plurality of electrically conductive layers 46 can be formed in the plurality of laterally-extending cavities, and a continuous metallic material layer can be formed on the sidewalls of each lateral isolation trench 79 and over the topmost insulating layer 32T. Each electrically conductive layer 46 includes a portion of the metallic barrier layer and a portion of the metallic fill material layer that are located between a vertically neighboring pair of dielectric material layers such as a pair of insulating layers 32. The continuous metallic material layer includes a continuous portion of the metallic barrier layer and a continuous portion of the metallic fill material layer that are located in the lateral isolation trenches 79 or above the contact-level dielectric layer 80.

The deposited metallic material of the continuous electrically conductive material layer is etched back from the sidewalls of each lateral isolation trench 79 and from above the topmost insulating layer 32T by performing an etch process that etches the at least one conductive material of the continuous electrically conductive material layer. Each remaining portion of the deposited metallic material in the laterally-extending cavities constitutes an electrically conductive layer 46. Each electrically conductive layer 46 can be a conductive line structure. Thus, the sacrificial material layers 42 are replaced with the electrically conductive layers 46.

A middle subset of the electrically conductive layers 46 can function as a combination of a plurality of control gate electrodes located at a same level and a word line electrically interconnecting, i.e., electrically shorting, the plurality of control gate electrodes located at the same level. The plurality of control gate electrodes within each electrically conductive layer 46 are the control gate electrodes for the vertical memory devices including the memory stack structures 55. In other words, the electrically conductive layer 46 can be a word line that functions as a common control gate electrode for the plurality of vertical memory devices. At least one upper most electrically conductive layer 46 may comprise a drain side select gate electrode. At least one lower most electrically conductive layer 46 may comprise a source side select gate electrode.

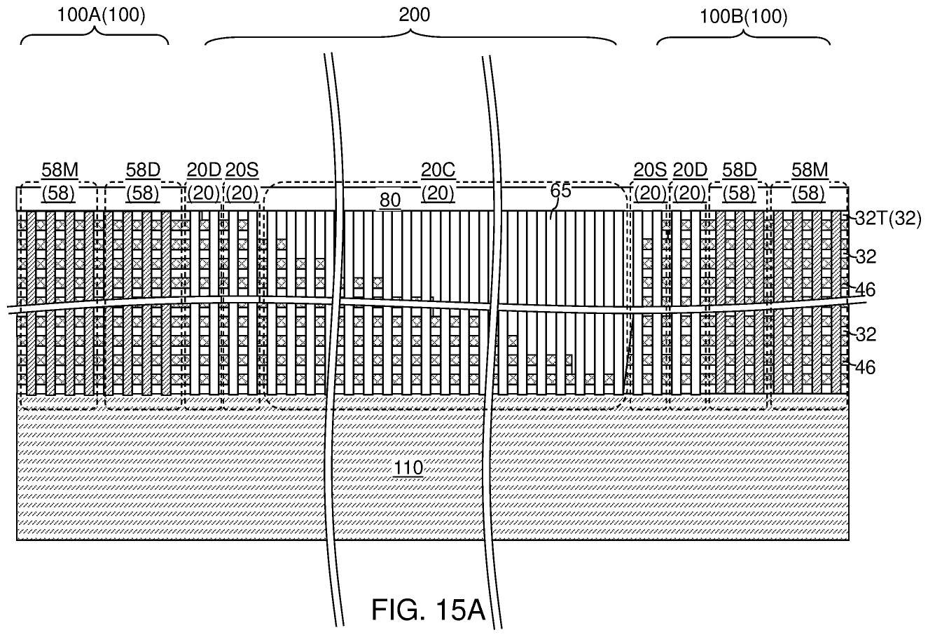

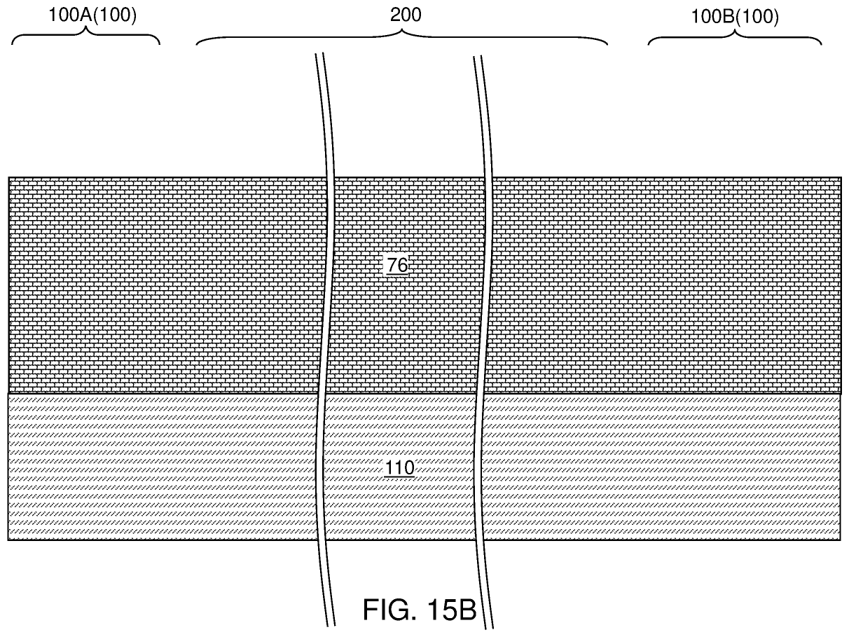

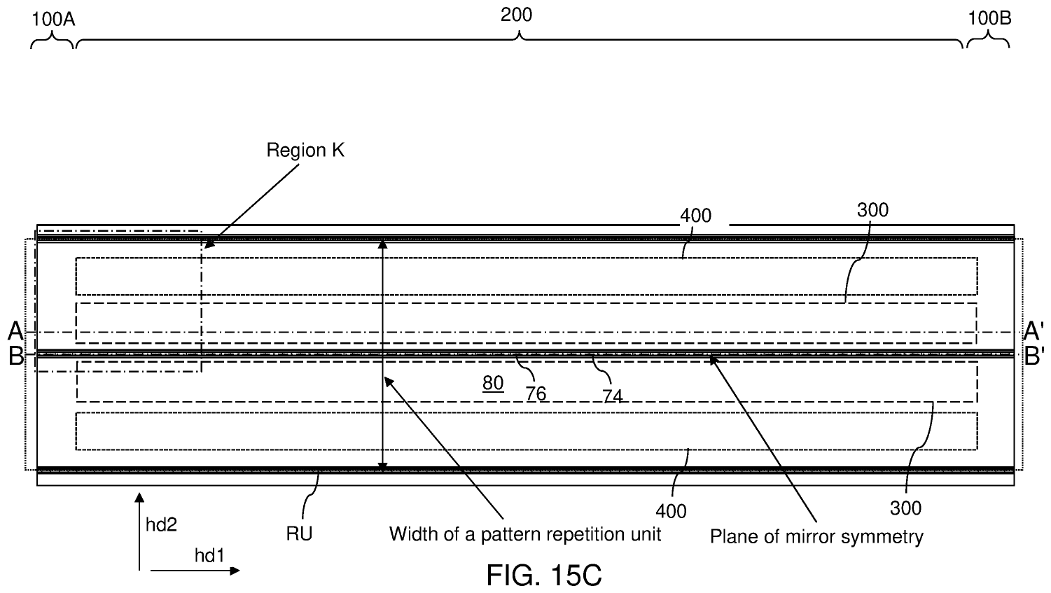

Referring to FIGS. 15A-15C, an insulating material layer can be conformally deposited in peripheral regions of the lateral isolation trenches 79. An anisotropic etch process can be performed to remove horizontally-extending portions of the insulating material layer. Each remaining portion of the insulating material layer in the lateral isolation trenches 79 constitute insulating spacers 74.

At least one conductive material, such as at least one metallic material, can be deposited in remaining volumes of the lateral isolation trenches 79. Excess portions of the at least one conductive material can be removed from above the horizontal plane including the top surface of the contact-level dielectric layer 80 by performing a planarization process, such as a chemical mechanical polishing process. Each remaining portion of the at least one conductive material in a respective one of the lateral isolation trenches 79 constitute a source contact wall structure 76. Each contiguous combination of an insulating spacer 74 and a source contact wall structure 76 constitutes an isolation trench fill structure (74, 76).

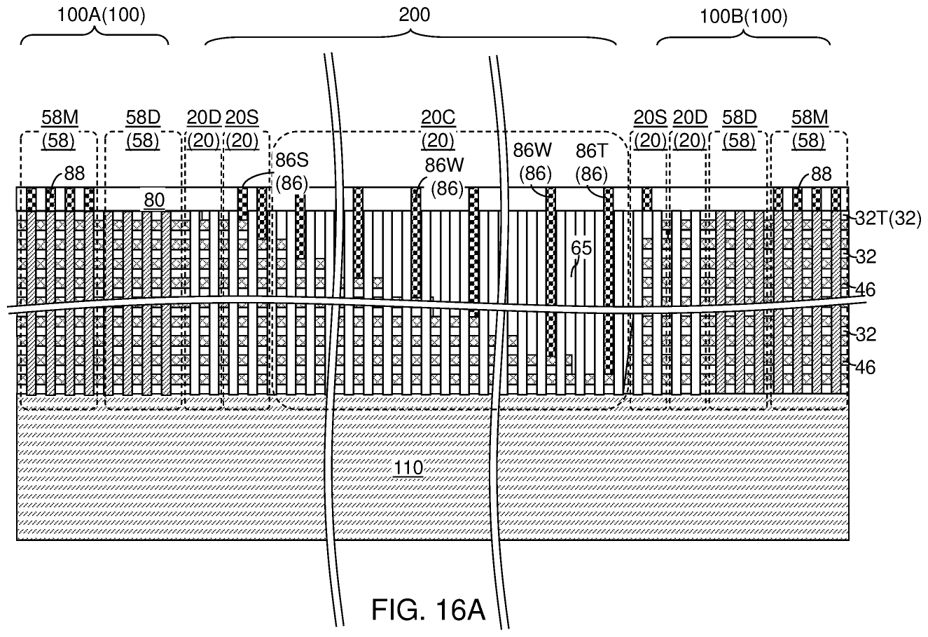

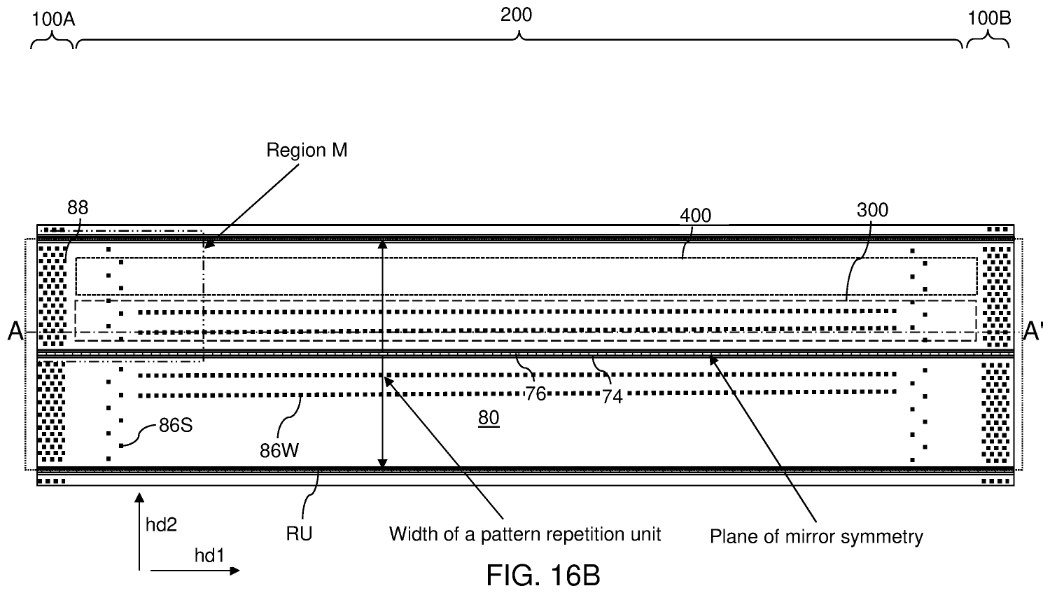

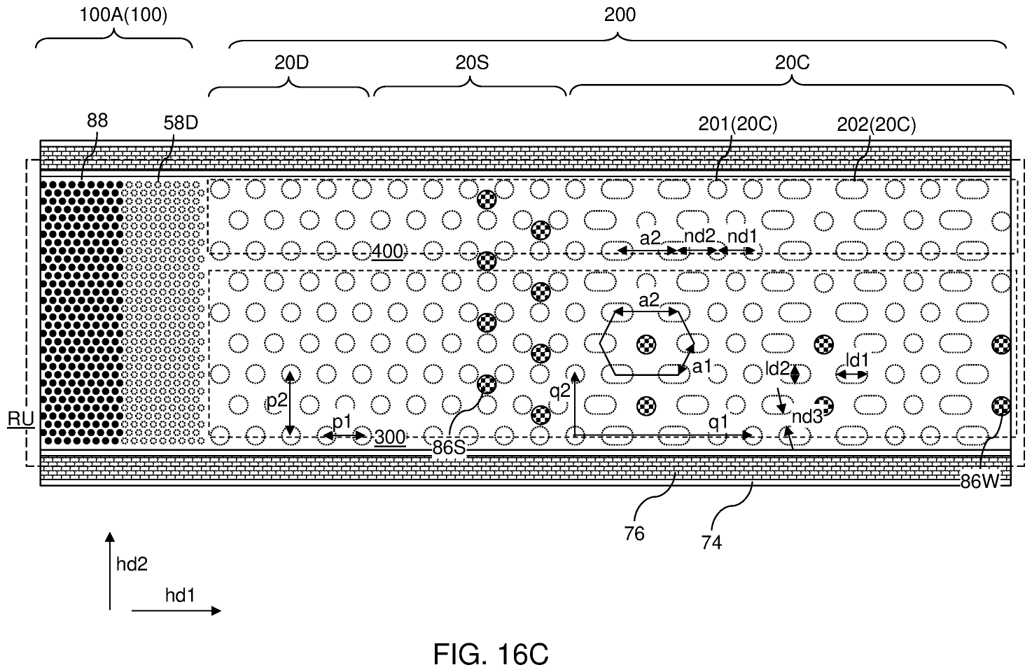

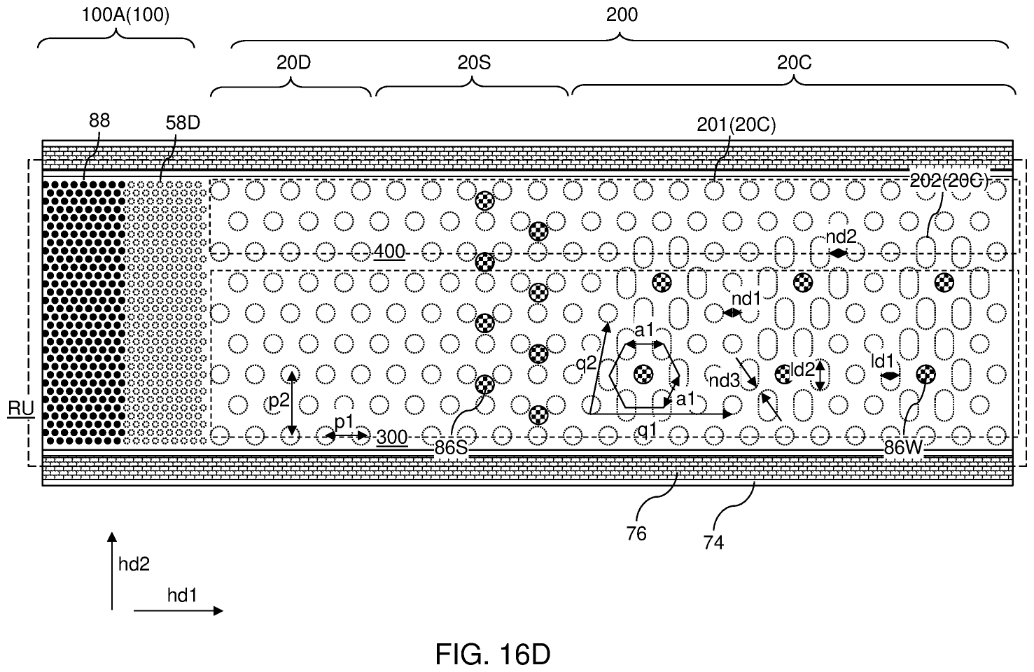

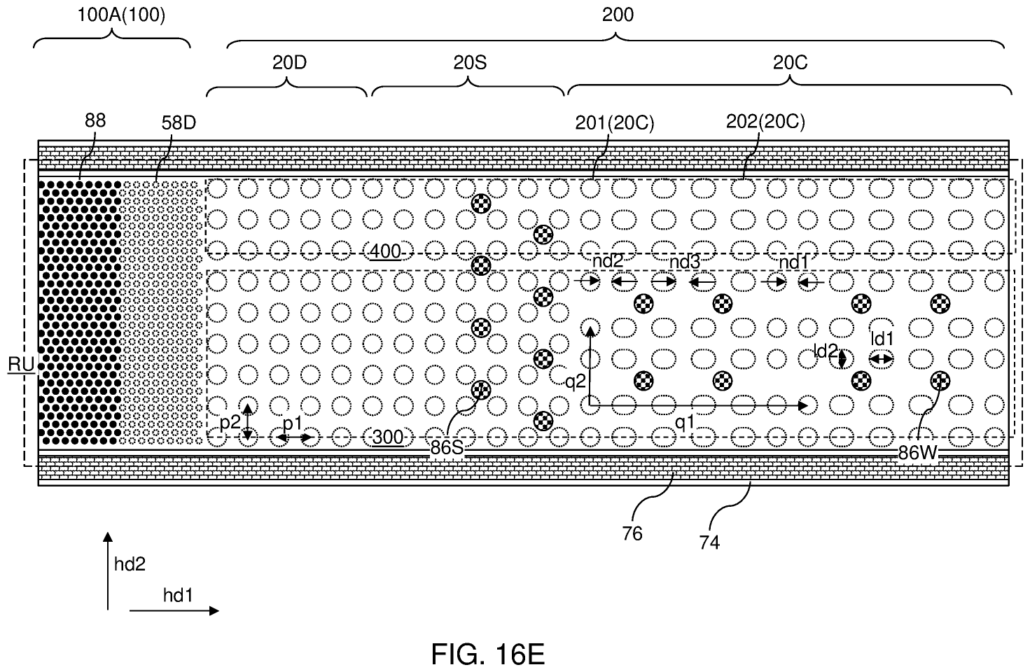

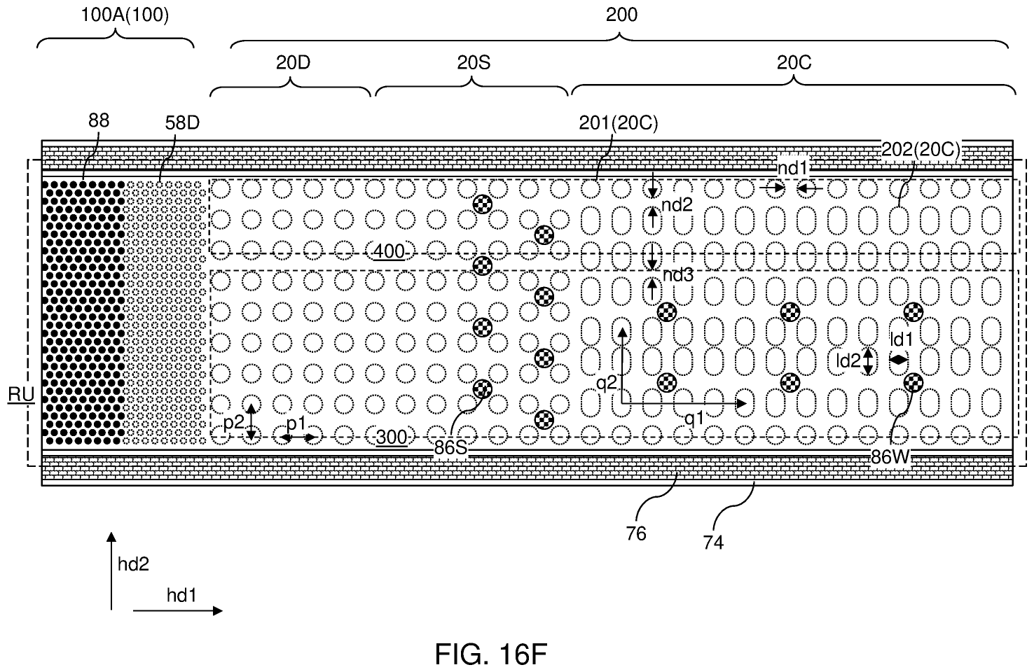

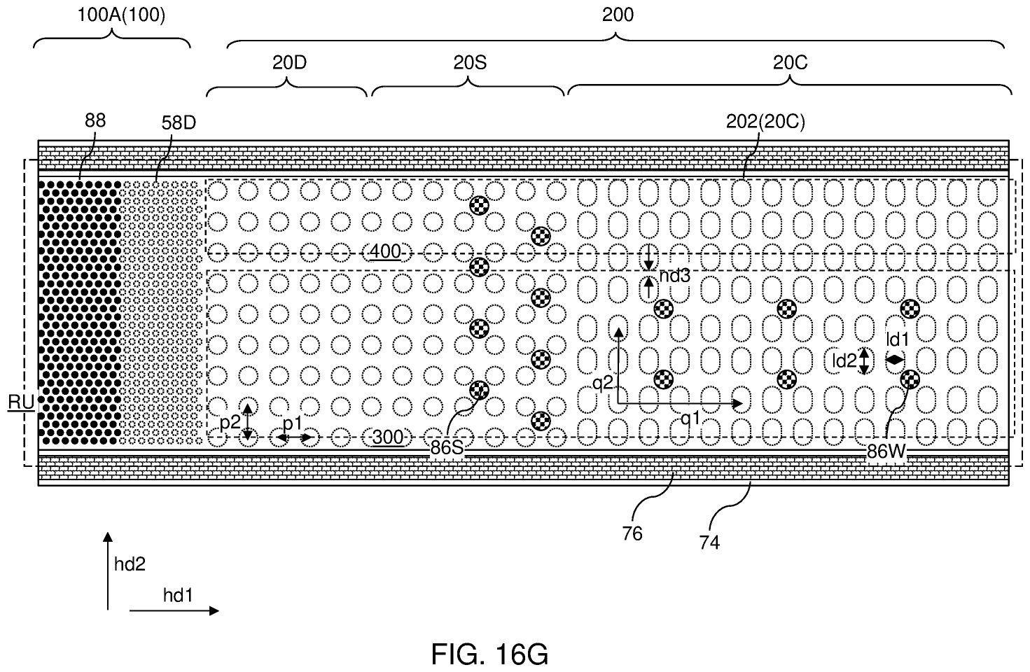

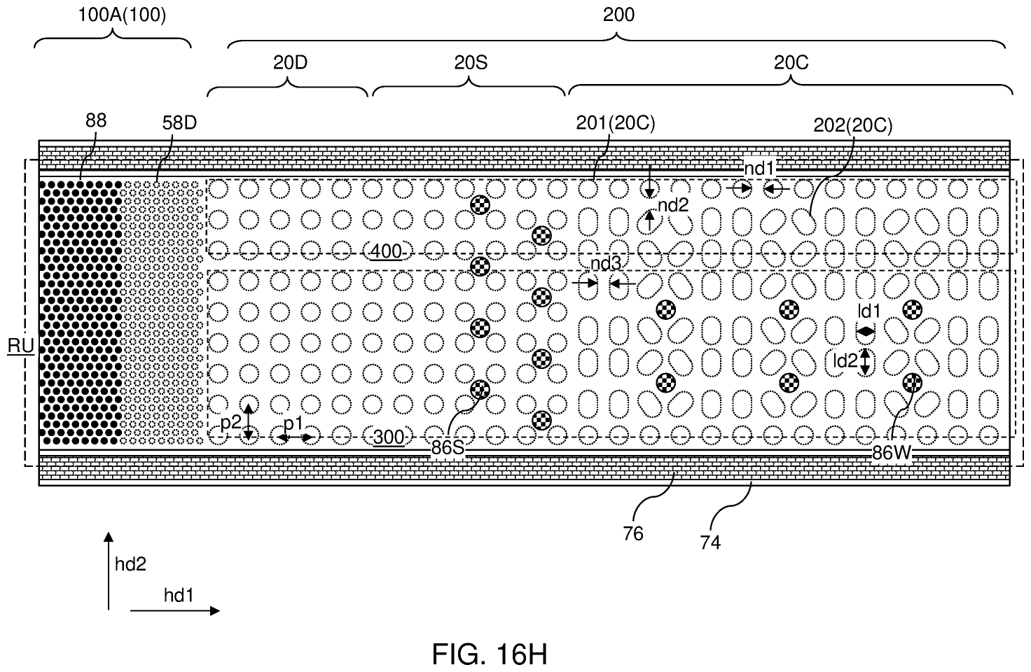

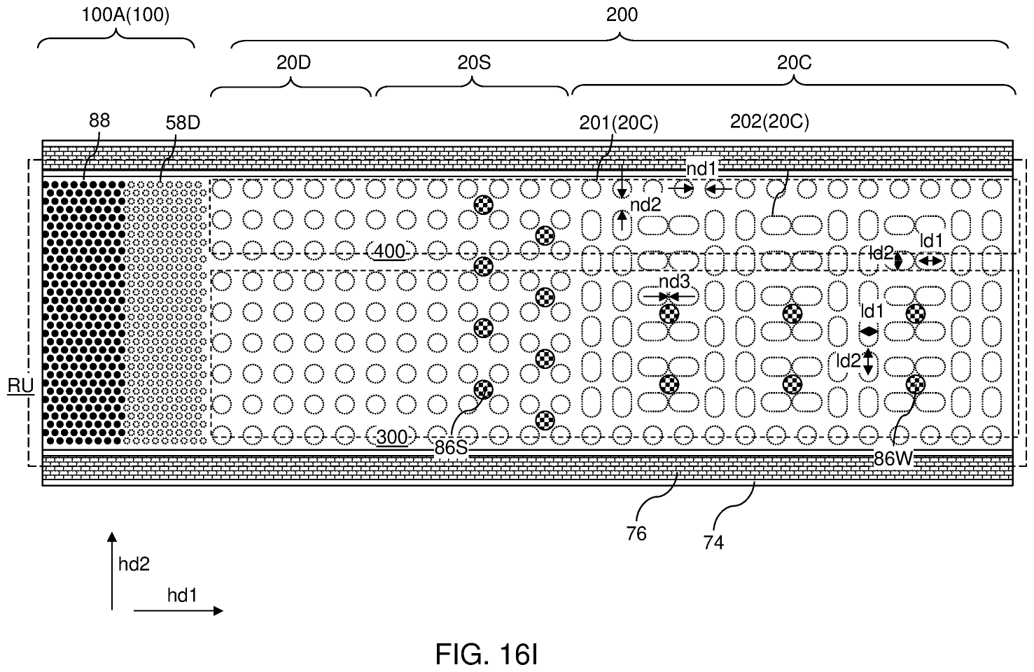

FIG. 16A is a vertical cross-sectional view of the exemplary structure after formation of layer contact via structures 86 and drain contact via structures 88 according to an embodiment of the present disclosure. FIG. 16B is a top-down view of the exemplary structure of FIG. 16A. FIGS. 16C-161 are top-down views of various configurations of the exemplary structure of FIGS. 16A and 16B.

Referring to FIGS. 16A-161, a photoresist layer (not shown) can be applied over the contact-level dielectric layer 80, and can be lithographically patterned to form openings over areas of the active memory opening fill structures 58M and horizontally-extending portions of the electrically conductive layers 46 that underlie the stepped bottom surfaces of the retro-stepped dielectric material portions 65. An anisotropic etch process can be performed to form drain contact via cavities over the drain regions 63 of the memory opening fill structures 58, and to form layer contact via structure cavities over the horizontally-extending surfaces of the electrically conductive layers 46 underlying the retro-stepped dielectric material portions 65. At least one conductive material can be deposited in the drain contact via cavities to form drain contact via structures 88, and can be deposited in the layer contact via structure cavities to form layer contact via structures 86. Each layer contact via structure 86 contacts a top surface segment of a respective electrically conductive layer 46. Each electrically conductive layer 46 can be contacted by at least one layer contact via structure 86. Additional metal interconnect structures (not shown) may be formed above the contact-level dielectric layer 80 as needed.

The layer contact via structures 86 comprise word-line-contact via structures 86W that are formed in electrical contact with the word lines, which are a subset of the electrically conductive layers 46 and are employed to access the memory elements within the three-dimensional array of memory elements. The word-line-contact via structures 86W can be formed within an area in which the primary dielectric pillar structures 20C are located. The layer contact via structures 86 further comprise drain-select-gate contact via structures 86S that are formed in electrical contact with the drain-select gate electrodes, which are another subset of the electrically conductive layers 46 including at least the topmost electrically conductive layer 46. The drain-select-gate contact via structures 86S can be formed within an area in which the auxiliary dielectric pillar structures 20S are located. Additional layer contact via structures 86 further comprise source-select-gate contact via structures 86T that are formed in electrical contact with the source-select gate electrodes, which are another subset of the electrically conductive layers 46 including at least the bottommost electrically conductive layer 46.

According to an aspect of the present disclosure, the word-line-contact via structures 86W can be formed at locations within the contact region 200 that is laterally surrounded by a respective subset of at least three of the primary dielectric pillar structures 20C. For example, the set of the primary dielectric pillar structures 20C may be arranged in a triangle, a rectangle (including a square), a pentagon or a hexagon. In one embodiment, the word-line-contact via structures 86W can be formed at locations within the contact region 200 that is laterally surrounded by a respective subset of at least three of the laterally-elongated dielectric pillar structures 202.

Referring to FIGS. 16A-161 and according to various embodiments of the present disclosure, a three-dimensional memory device includes an alternating stack (32, 46) of insulating layers 32 and electrically conductive layers 46, memory stack structures 55 vertically extending through the alternating stack, and each of the memory stack structures 55 includes a respective vertical stack of memory elements (e.g., portions of the memory film 50) and a vertical semiconductor channel 60, support pillar structures 20 vertically extending through the alternating stack (32, 45) in a contact region 200, and word-line-contact via structures 86W located within the contact region 200 and electrically contacting a respective one of the electrically conductive layers 46. The support pillar structures 20 include laterally-elongated support pillar structures 202 having a respective laterally-elongated horizontal cross-sectional shape, and cylindrical support pillar structures (201, 20D and/or 20S) having a respective circular cross-sectional shape. Each of the word-line-contact via structures 86W is laterally surrounded by a respective set of at least three (e.g., three, four, five or six) laterally-elongated support pillar structures 202.

In one embodiment, the support pillar structures comprise dielectric pillar structures 20, the laterally-elongated support pillar structures comprise laterally-elongated dielectric pillar structures 202, and the cylindrical support pillar structures comprise cylindrical dielectric pillar structures (201, 20D and/or 20S). In one embodiment, the dielectric pillar 20 structures consist essentially of silicon oxide, the laterally-elongated dielectric pillar structures 202 consist essentially of silicon oxide, and the cylindrical dielectric pillar structures (201, 20D and/or 20S) consist essentially of silicon oxide.

The various embodiments of the present disclosure provide various configurations of dielectric pillar structures (20D, 20S, 20C) that provide mechanical support to a three-dimensional memory device during replacement of sacrificial material layers 42 with electrically conductive layers 46. The dielectric pillar structures (20D, 20S, 20C) can be arranged to accommodate layer contact via structures 86 that are subsequently formed directly on top surfaces of the electrically conductive layers 46 and to reduce the size of the contact region 200.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph of in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A three-dimensional memory device, comprising:
an alternating stack of insulating layers and electrically conductive layers;
memory stack structures vertically extending through the alternating stack,
wherein each of the memory stack structures comprises a respective vertical stack of memory elements and a vertical semiconductor channel;
support pillar structures vertically extending through the alternating stack in a contact region; and
word-line-contact via structures located within the contact region and electrically contacting a respective one of the electrically conductive layers,
wherein:
the support pillar structures comprise laterally-elongated support pillar structures having a respective laterally-elongated horizontal cross-sectional shape and cylindrical support pillar structures having a respective circular cross-sectional shape; and
each of the word-line-contact via structures is laterally surrounded by a respective set of at least three laterally-elongated support pillar structures.

2. The three-dimensional memory device of claim 1, wherein the support pillar structures comprise dielectric pillar structures, the laterally-elongated support pillar structures comprise laterally-elongated dielectric pillar structures, and the cylindrical support pillar structures comprise cylindrical dielectric pillar structures.

3. The three-dimensional memory device of claim 2, wherein the dielectric pillar structures consist essentially of silicon oxide, the laterally-elongated dielectric pillar structures consist essentially of silicon oxide, and the cylindrical dielectric pillar structures consist essentially of silicon oxide.

4. The three-dimensional memory device of claim 2, wherein each of the word-line-contact via structures is laterally surrounded by the respective set of six hexagonally-arranged laterally-elongated dielectric pillar structures that are located at six vertices of a respective elongated hexagon in a plan view.

5. The three-dimensional memory device of claim 4, wherein the cylindrical dielectric pillar structures are located between neighboring sets of hexagonally-arranged laterally-elongated dielectric pillar structures.

6. The three-dimensional memory device of claim 5, wherein:
each of the laterally-elongated dielectric pillar structures has a maximum lateral dimension along a lateral pillar elongation direction that is greater than a diameter of each of the cylindrical dielectric pillar structures;
each of the hexagons is laterally elongated along a lateral hexagon elongation direction which is the same as the lateral pillar elongation direction;
the alternating stack laterally extends along a first horizontal direction and has a uniform width along a second horizontal direction that is perpendicular to the first horizontal direction; and
the memory stack structures comprise first memory stack structures located in a first memory array region and second memory stack structures located in a second memory array region that is laterally spaced from the first memory array region by the contact region.

7. The three-dimensional memory device of claim 6, wherein the lateral hexagon elongation direction is the first horizontal direction.

8. The three-dimensional memory device of claim 6, wherein the lateral hexagon elongation direction is the second horizontal direction.

9. The three-dimensional memory device of claim 2, wherein:
the laterally-elongated dielectric pillar structures are laterally elongated along a lateral pillar elongation direction, and are arranged in multiple rows of laterally-elongated dielectric pillar structures that laterally extend along the lateral pillar elongation direction; and
each of the word-line-contact via structures is laterally surrounded by the respective set of four rectangularly-arranged laterally-elongated dielectric pillar structures that are located at four vertices of a respective rectangle in a plan view.

10. The three-dimensional memory device of claim 9, wherein nearest neighbor distances within each row of laterally-elongated dielectric pillar structures have a modulation along the lateral pillar elongation direction.

11. The three-dimensional memory device of claim 9, wherein the multiple rows of laterally-elongated dielectric pillar structures have a uniform row-to-row pitch along a horizontal direction that is perpendicular to the lateral pillar elongation direction.

12. The three-dimensional memory device of claim 9, wherein each of the rectangles is laterally elongated along a lateral rectangle elongation direction which is the same as the lateral pillar elongation direction.

13. The three-dimensional memory device of claim 2, wherein the laterally-elongated support pillar structures comprise:
first laterally-elongated dielectric pillar structures that are laterally elongated along a first lateral pillar elongation direction, and are arranged in multiple rows each laterally extending along a row direction that is the same as the first lateral pillar elongation direction; and
second laterally-elongated dielectric pillar structures that are elongated along a respective lateral pillar elongation direction that is different from the first pillar elongation direction.

14. The three-dimensional memory device of claim 13, wherein each of the word-line-contact via structures is laterally surrounded by the respective subset of four second laterally-elongated dielectric pillar structures that are located at four vertices of a respective rectangle in a plan view.

15. The three-dimensional memory device of claim 13, wherein nearest neighbor distances within each row of first laterally-elongated dielectric pillar structures have a modulation along the first lateral pillar elongation direction.

16. The three-dimensional memory device of claim 13, wherein the multiple rows of laterally-elongated dielectric pillar structures have a uniform row-to-row pitch along a horizontal direction that is perpendicular to the first lateral pillar elongation direction.

17. The three-dimensional memory device of claim 13, wherein each of the second laterally-elongated dielectric pillar structures is elongated along a second lateral pillar elongation direction that is perpendicular to the first lateral pillar elongation direction.

18. The three-dimensional memory device of claim 13, wherein the second laterally-elongated dielectric pillar structures are elongated along multiple lateral pillar elongation directions that is azimuthally offset the first lateral pillar elongation direction by a respective azimuthal angle in a range from −60 degrees to +60 degrees.

19. The three-dimensional memory device of claim 13, wherein:
the alternating stack laterally extends along a first horizontal direction and has a uniform width along a second horizontal direction that is perpendicular to the first horizontal direction;
the memory stack structures comprise first memory stack structures located in a first memory array region and second memory stack structures located in a second memory array region that is laterally spaced from the first memory array region by the contact region; and
the first lateral pillar elongation direction is perpendicular to the first horizontal direction.

20. The three-dimensional memory device of claim 1, wherein the laterally-elongated horizontal cross-sectional shape of the laterally-elongated support pillar structures comprise an elliptical shape having a length-to-width ratio in a range from 1.1 to 3.
